(19) United States
(12) Patent Application Publication
(10) Pub. No.: US 2025/0349745 A1
(43) Pub. Date: Nov. 13, 2025

(54) SEMICONDUCTOR DEVICE AND MANUFACTURING METHOD THEREOF

(71) Applicants: nD-HI Technologies Lab, Inc., Taipei City (TW); ETRON TECHNOLOGY, INC., Hsinchu (TW)

(72) Inventors: Ho-Ming TONG, Taipei City (TW); Chao-Chun LU, Hsinchu (TW)

(73) Assignees: nD-HI Technologies Lab, Inc., Taipei City (TW); ETRON TECHNOLOGY, INC., Hsinchu (TW)

(21) Appl. No.: 19/203,757

(22) Filed: May 9, 2025

Related U.S. Application Data
(60) Provisional application No. 63/644,711, filed on May 9, 2024.
(60) Provisional application No. 63/686,185, filed on Aug. 23, 2024.

(51) Int. Cl. H01L 23/00; H01L 21/48; H01L 21/56; H01L 23/16; H01L 23/31; H01L 23/498

(52) U.S. Cl. CPC H01L 23/562; H01L 21/4857; H01L 21/565; H01L 21/568; H01L 23/16; H01L 23/3128; H01L 23/49816; H01L 23/49822

(57) ABSTRACT

A semiconductor device includes a cage, a semiconductor chip, a package body and a first RDL (redistribution layer). The cage has a first cage surface, a second cage surface opposite to the first cage surface and a cavity extending towards the second cage surface from the first cage surface. The semiconductor chip is disposed in the cavity. The package body covers the semiconductor chip. The first RDL is disposed over the package body and the semiconductor chip.

This application claims the benefit of U.S. provisional application Ser. No. 63/644,711, filed May 9, 2024, the subject matter of which is incorporated herein by reference, and claims the benefit of U.S. provisional application Ser. No. 63/686,185, filed Aug. 23, 2024, the subject matter of which is incorporated herein by reference.

### BACKGROUND

### Technical Field

The disclosure relates in general to a semiconductor device and a manufacturing method thereof.

### Description of the Related Art

The chip (or die) and substrate need to be aligned to ensure accurate contact between them. In general, chip shift/sliding may be caused by (1) differences in CTE (coefficient of thermal expansion) between the chip and the substrate, and (2) chip sizes. The greater the size of the chip is, the greater the warpage of the substrate is. The greater warpage may result in the inaccurate contact.

### SUMMARY

According to a first aspect of the present disclosure, a semiconductor device is provided. The semiconductor device includes a cage, a semiconductor chip, a package body and a first RDL (redistribution layer). The cage has a first cage surface, a second cage surface opposite to the first cage surface and a cavity extending towards the second cage surface from the first cage surface. The semiconductor chip is disposed in the cavity. The package body covers the semiconductor chip. The first RDL is disposed over the package body and the semiconductor chip.

In an embodiment, the cavity extends to the first cage surface.

In an embodiment, the semiconductor chip has a chip back surface, and the chip back surface of the semiconductor chip and the second cage surface of the cage are flushed with each other.

In an embodiment, the semiconductor chip protrudes relative to the first cage surface of the cage.

In an embodiment, the package body has a package lateral surface, the cage has a cage lateral surface, and the package lateral surface and the cage lateral surface are flushed with each other.

In an embodiment, the cage has a cage lateral surface, and the package body covers the cage lateral surface and the first cage surface but exposes the second cage surface.

In an embodiment, the cavity is a blind hole in the cage which is a substrate, and the semiconductor chip is a flip chip having an active surface, and the flip chip is bonded to the substrate in the blind hole with the active surface facing the blind hole.

In an embodiment, the semiconductor chip is a flip chip having an active surface, the first RDL is disposed on the second cage surface and the active surface, and the package body covers the first cage surface of the cage.

In an embodiment, the semiconductor device further includes a conductive layer within the cavity. the semiconductor chip is disposed on the conductive layer, the package body has a package surface and a through hole extending to the conductive layer from the package surface; and the semiconductor device further includes a conductive portion within the through hole.

In an embodiment, the semiconductor device further includes a conductive portion extending to the first cage surface from the second cage surface.

In an embodiment, the semiconductor device further includes a second RDL disposed on the second cage surface; and a third RDL disposed on the first cage surface and between the first RDL and the first cage surface. The conductive portion electrically connects the second RDL with the third RDL.

In an embodiment, the package body is disposed within the cavity and disposed between a lateral surface of the semiconductor chip and a lateral surface of the cavity.

According to a second aspect of the present disclosure, a manufacturing method of a semiconductor device is provided. The manufacturing method includes the following steps: disposing a cage on a carrier, wherein the cage has a first cage surface, a second cage surface opposite to the first cage surface and a cavity extending toward the second cage surface from the first cage surface; disposing a semiconductor chip in the cavity; disposing a package body to cover the semiconductor chip; disposing a first RDL over the package body and the semiconductor chip; and removing the carrier to expose the first RDL.

In an embodiment, step of disposing the first RDL over the package body and the semiconductor chip includes disposing the first RDL on a carrier; transfer the first RDL to the package body and the semiconductor chip through the carrier; and removing the carrier.

In an embodiment, the manufacturing method further includes: removing the cage and a portion of the semiconductor chip.

In an embodiment, in step of disposing the package body to cover the semiconductor chip, the package body further covers a lateral surface of the cage.

In an embodiment, the cage containing the cavity in form of a blind hole is disposed on the carrier; and the semiconductor chip is a flip chip bonded in the blind hole with an active surface facing the blind hole.

In an embodiment, the manufacturing method further includes: disposing a conductive layer within the cavity; disposing the semiconductor chip in the cavity on the conductive layer; disposing the package body to cover the semiconductor chip; forming a through hole which extends to the conductive layer from a package surface of the package body; and forming a conductive portion within the through hole.

In an embodiment, step of disposing the cage on the carrier includes: forming a conductive portion, wherein the conductive portion extends to the first cage surface from the second cage surface.

In an embodiment, step of disposing the cage on the carrier includes: disposing a second RDL on the second cage surface; and disposing a third RDL on the first cage surface, wherein the third RDL is disposed between the first RDL and the. first cage surface, and the conductive portion electrically connecting the second RDL with the third RDL.

In an embodiment, in disposing the package body to cover the semiconductor chip, the package body is disposed within the cavity and disposed between a lateral surface of the semiconductor chip and a lateral surface of the cavity.

The present invention is mainly aimed at the chip packaging reconstruction process of wafer-level packaging or panel-level packaging products. Because the molding compound may cause the chip position to move during the package covering process, thereby affecting the operability and stability of the subsequent process (such as RDL production)”, various package structures and manufacturing process improvements are proposed to improve and ensure the final high yield and output of the product.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a diagram view of a semiconductor device according to an embodiment of the disclosure;

FIG. 1B illustrates a diagram view of a cross-sectional view of the semiconductor device in FIG. 1A along a direction 1B-1B′;

FIG. 2 illustrates a diagram view of a cross-sectional view of a semiconductor device according to another embodiment of the disclosure;

FIG. 3 illustrates a diagram view of a cross-sectional view of a semiconductor device according to another embodiment of the disclosure;

FIG. 4 illustrates a diagram view of a cross-sectional view of a semiconductor device according to another embodiment of the disclosure;

FIG. 5 illustrates a diagram view of a cross-sectional view of a semiconductor device according to another embodiment of the disclosure;

FIG. 6 illustrates a diagram view of a cross-sectional view of a semiconductor device according to another embodiment of the disclosure;

FIG. 7 illustrates a diagram view of a cross-sectional view of a semiconductor device according to another embodiment of the disclosure;

FIG. 8 illustrates a diagram view of a semiconductor device according to an embodiment of the disclosure;

FIGS. 9A to 9I illustrate schematic diagrams of manufacturing method of the semiconductor device in FIG. 1B according to an embodiment of the disclosure;

FIGS. 10A to 10C illustrate schematic diagrams of manufacturing method of the semiconductor device in FIG. 1B according to another embodiment;

FIGS. 11A to 11C illustrate schematic diagrams of manufacturing method of the semiconductor device in FIG. 2 according to an embodiment;

FIGS. 12A to 121 illustrate schematic diagrams of manufacturing method of the semiconductor device in FIG. 3 according to an embodiment;

FIGS. 13A to 13C illustrate schematic diagrams of manufacturing method of the semiconductor device in FIG. 3 according to another embodiment;

FIGS. 14A to 14I illustrate schematic diagrams of manufacturing method of a semiconductor device according to another embodiment;

FIGS. 15A to 15I illustrate schematic diagrams of manufacturing method of the semiconductor device in FIG. 2 according to another embodiment;

FIGS. 16A to 16G illustrate schematic diagrams of manufacturing method of the semiconductor device in FIG. 4 according to an embodiment;

FIGS. 17A to 17J illustrate schematic diagrams of manufacturing method of the semiconductor device in FIG. 5 according to an embodiment;

FIGS. 18A to 18I illustrate schematic diagrams of manufacturing method of the semiconductor device in FIG. 6 according to an embodiment;

FIGS. 19A to 19J illustrate schematic diagrams of manufacturing method of the semiconductor device in FIG. 7 according to an embodiment;

FIGS. 20A to 20C illustrate schematic diagrams of manufacturing method of the semiconductor device in FIG. 7 according to another embodiment;

FIGS. 21A to 21G illustrate schematic diagrams of manufacturing method of the semiconductor device in FIG. 8 according to an embodiment;

FIG. 22A illustrates a schematic diagram of a panel-level packaging according to an embodiment; and

FIG. 22B illustrates a schematic diagram of a cross-sectional view of the panel-level packaging in FIG. 22A along a direction 22B-22B′.

### DETAILED DESCRIPTION

Several embodiments are disclosed below for elaborating the invention. Those embodiments are for the purpose of elaboration only, not for limiting the scope of protection of the invention. Besides, secondary elements are omitted in the following embodiments to highlight the technical features of the invention.

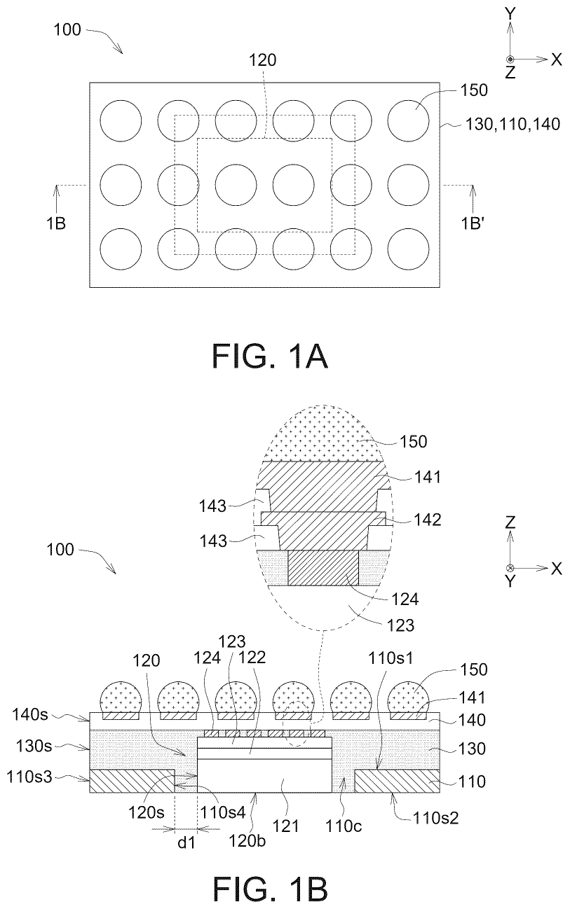

Referring to FIGS. 1A and 1B, FIG. 1A illustrates a diagram view of a semiconductor device 100 according to an embodiment of the disclosure, and FIG. 1B illustrates a diagram view of a cross-sectional view of the semiconductor device 100 in FIG. 1A along a direction 1B-1B′.

As illustrated in FIGS. 1A and 1B, the semiconductor device 100 includes at least one cage 110, at least one semiconductor chip 120, a package body 130, a first RDL (redistribution layer) 140 and at least one contact 150. The cage 110 has a first cage surface 110s1, a second cage surface 110s2 opposite to the first cage surface 110s1 and a cavity 110c extending towards the second cage surface 110s2 from the first cage surface 110s1. The semiconductor chip 120 is disposed in the cavity 110c. The package body 130 covers the semiconductor chip 120. The first RDL 140 is disposed over the package body 130 and the semiconductor chip 120. The cage 110 may constrain a displacement of the semiconductor chip 120. Furthermore, in process of manufacturing the semiconductor device 100, the semiconductor chip 120 may be placed in the cavity 110c of the cage 110 for being restricted in the cavity 110c, and accordingly it may increase the positioning accuracy of the semiconductor chip 120 and the first RDL 140.

Furthermore, die shift/sliding is caused by: (1). differences in CTE (coefficient of thermal expansion) between the carrier, the molding compound, and the embedded die, and the chemical shrinkage of the molding compound; and is influenced by (2). die sizes, adhesion of the dies on the release layer and the flow behavior of the molding compound and related forces on the dies during compression molding. Geometries (e.g., carrier type and thickness, mold thickness, die thickness, overall silicon content/density, lateral panel dimensions, etc.) also play a significant role in both die shift/sliding and panel warpage. The solutions in the present application include, but not limited to, die cage/stopper/restraint, permanent die bonding, related processes, and adaptive patterning may help minimize the impact.

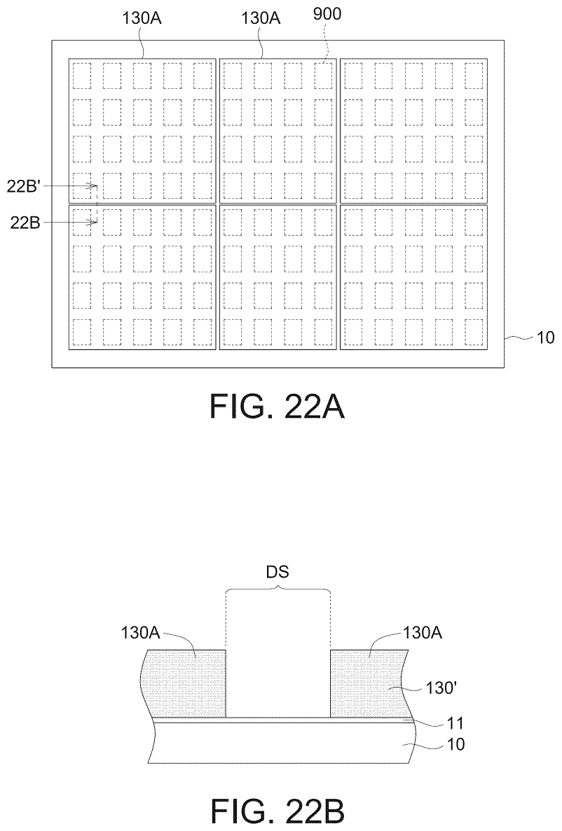

In addition, warpage is also caused by differences in CTE between the carrier, the molding compound, the embedded die and is influenced by the chemical shrinkage of the molding compound. The geometries (e.g., carrier type and thickness, mold thickness, die thickness, overall silicon content/density, lateral panel dimensions, etc.) also play a significant role in both die shift/sliding and panel warpage. The solutions in the present application includes thicker, more rigid carrier (including framed handling)/support substrate) with a sufficient thickness and thermo-mechanical properties (e.g., CTE, modulus, etc.) may be used to minimize warpage; separated over-mold islands (see FIGS. 22A and 22B) may be used to separate blocks of dies from others to minimize the CTE mismatch, mold flow and other effects; a lower-CTE, lower-modulus molding compound or encapsulation material, and adaptive patterning can be used to minimize warpage effects.

In addition, fine-line/space (L/S) capabilities in the semiconductor device may be equal to or less than 2/2 μm. Significant FOPLP process development needs to occur to address the significant technology process and material challenges that come with the immensely greater area of a panel. Building more finer-L/S RDL layers on the large panel leads to lower yields and higher levels of die scraps. The solutions in the present application includes heterogeneous integration of wafer and substrate technologies with FOPLP can of assistance (e.g., build the finer-L/S RDLs on a carrier wafer, test them to ensure known-good structures, dice the wafer, bond the know-good RDLs to the chips on the panel); using spray coating of liquid resist to create fine-L/S RDLs for horizontal-level RDL, and laser drilling, DRIE, dry Ar de-smear, physical vapor deposition of barrier/seed layer, a dry film, a metal hard mask, copper pillar plating, wet cleaning and a combination thereof to form vertical-level fine-L/S RDLs; and implementing build-in RDL test circuitry (e.g., daisy chains), multi-site panel-level test and/or chip related built-in self test (BIST).

In the present embodiment, the cage 110 may be formed of a material including metal, glass, ceramics, etc. In an embodiment, the cage 110 does not include any circuit element.

As illustrated in FIG. 1A, the cage 110 is shaped as a closed-ring. In another embodiment, the cage 110 may be shaped as an opened-ring. Viewed in a top direction (toward-Z axis), the cage 110 may be a polygonal shape (for example, rectangle, triangle, etc.), a circle, ellipse, etc. The cage 110 has a first cage lateral surface 110s3 and a second cage lateral surface 110s4 opposite to the first cage lateral surface 110s3. A distance d1 of the second cage lateral surface 110s4 of the cage 110 and a lateral surface 120s of the semiconductor chip 120 may range between, for example, 1 micrometer and 10 micrometers, such as 1 micrometer, 2 micrometers, 3 micrometers, 4 micrometers, 5 micrometers, 6 micrometers, 7 micrometers, 8 micrometers, 9 micrometers or 10 micrometers. Such distance d1 may increase the positioning accuracy of the semiconductor chip 120 and the first RDL 140.

In the present embodiment, the cavity 110c is a through hole. For example, the cavity 110c extends to the first cage surface 110s1 from the second cage surface 110s2. In another embodiment, the cavity 110c is, for example, a blind hole.

As illustrated in FIG. 1B, the semiconductor chip 120 includes a base 121, a FEOL (Front-End-Of-Line) structure 122, a BEOL (Back-End-Of-Line) structure 123 and at least one contact 124. The base 121 is, for example, a portion of a silicon wafer. The FEOL structure 122 is formed in and/or on the base 121, the BEOL structure 123 is formed in and/or on the FEOL structure 122 and electrically connected with the FEOL structure 122, and the contact 124 is formed on the BEOL structure 123 and electrically connected with the BEOL structure 123. The contact 124 is, for example, a solder ball, a micro bump, a micro pillar, etc.

As illustrated in FIG. 1B, the semiconductor chip 120 has a chip surface (chip back surface) 120b, wherein the chip surface 120b is exposed from the cavity 110c, and the chip surface 120b of the semiconductor chip 120 and the second cage surface 110s2 of the cage 110 are, for example, aligned with (for example, flushed with) each other. In addition, the semiconductor chip 120 protrudes relative to the first cage surface 110s1 of the cage 110.

As illustrated in FIG. 1B, the package body 130 encapsulates the cage 110 and the semiconductor chip 120. For example, the package body 130 covers the first cage surface 110s1 and the second cage lateral surface 110s4 of the cage 110, the lateral surface 120s of the semiconductor chip 120 and the lateral surfaces of the contact 124, but exposes the second cage surface 110s2 and the first cage lateral surface 110s3 of the cage 110. In addition, the package body 130 further fills up a portion of the cavity 110c.

As illustrated in FIG. 1B, the package body 130 has a package lateral surface 130s, and the package lateral surface 130s and the first cage lateral surface 110s3 are, for example, aligned with (for example, flushed with) each other. Furthermore, in process of manufacturing the semiconductor device 100, the package lateral surface 130s and the first cage lateral surface 110s3 are formed by, for example, a singulation (for example, by sawing, such as diamond blade sawing or laser sawing).

In addition, the package body 130 is, for example, a molding compound, a laminated photoresist, etc. The molding compound includes materials such as a Novolac-based resin, an epoxy-based resin, a silicone-based resin or another suitable encapsulant, and may contain suitable fillers such as powdered SiO₂. The molding compound may be formed by using, for example, transfer molding, compression molding, lamination, etc.

As illustrated in FIG. 1B, the first RDL 140 is disposed on and/or above the package body 130 and the semiconductor chip 120. The first RDL 140 is electrically connected with the semiconductor chip 120. For example, the first RDL 140 is electrically connected with the contact 124 of the semiconductor chip 120. The first RDL 140 at least includes at least one conductive pad 141 for receiving the contact 150. Due to the semiconductor chip 120 being restricted in the cavity 110c, it may increase the positioning accuracy of the contact 124 of the semiconductor chip 120 and the conductive pad 141 of the first RDL 140. The first RDL 140 includes the conductive portion 142 and the dielectric layer 143. In addition, the first RDL 140 has a RDL lateral surface 140s, and the RDL lateral surface 140s and the first cage lateral surface 110s3 are, for example, aligned with (for example, flushed with) each other. Furthermore, in process of manufacturing the semiconductor device 100, the RDL lateral surface 140s and the first cage lateral surface 110s3 are formed by, for example, a singulation (for example, by sawing, such as diamond blade sawing or laser sawing). The conductive portion 142 may be formed of a material including metal, such as copper, etc., and the dielectric layer 143 may be formed of a material including polyimide (PI), oxide, etc.

As illustrated in FIG. 1B, the contacts 150 are disposed on the first RDL 140. For example, each contact 150 is disposed on the corresponding the conductive pad 141 of the first RDL 140. The semiconductor device 100 is, for example, a BGA (Ball Grid Array), and the contact 150 is, for example, a solder ball (or called a BGA ball), micro bump, etc.

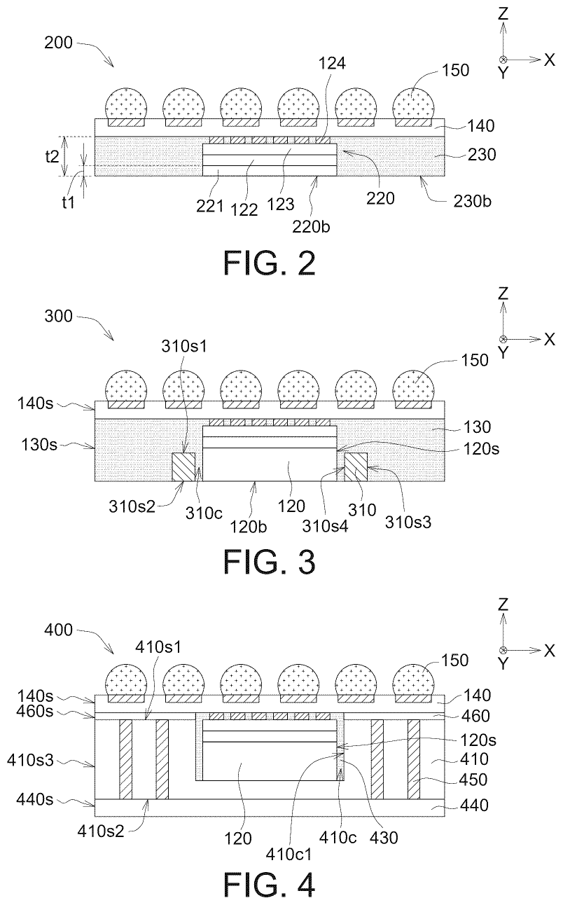

Referring to FIG. 2, FIG. 2 illustrates a diagram view of a cross-sectional view of a semiconductor device 200 according to another embodiment of the disclosure.

As illustrated in FIG. 2, the semiconductor device 200 includes at least one semiconductor chip 220, a package body 230, the first RDL 140 and at least one contact 150. The semiconductor device 200 includes the feature the same as or similar to that of the semiconductor device 100, and at least one difference is that the semiconductor device 200 may omit the cage 110.

As illustrated in FIG. 2, the semiconductor chip 220 includes a base 221, the FEOL structure 122, the BEOL structure 123 and at least one contact 124. The base 221 is, for example, a portion of a silicon wafer. The FEOL structure 122 is formed in and/or on the base 221, the BEOL structure 123 is formed in and/or on the FEOL structure 122 and electrically connected with the FEOL structure 122, and the contact 124 is formed on the BEOL structure 123 and electrically connected with the BEOL structure 123. The contact 124 is, for example, a solder ball, a micro bump, a micro pillar, etc.

As illustrated in FIG. 2, the base 221 has a thickness t1. Compared to the base 121 in FIG. 1B, thickness t1 of the base 221 is less than a thickness of the base 121 in the same direction. The package body 230 has a thickness t2. Compared to the package body 130 in FIG. 1B, the thickness t2 of the package body 230 is less than a thickness of the package body 130 in the same direction. Furthermore, in process of manufacturing the semiconductor device 200, the cage 110 and a portion of the semiconductor chip 120, a portion of the package body 130 in FIG. 1B may be removed by using, for example, grinding. After removing, the thinned semiconductor chip 220 and the thinned package body 230 is formed. After removing, the base 221 of the semiconductor chip 220 forms a chip surface 220b, and the package body 230 forms a package surface 230b, wherein the chip surface 220b of the semiconductor chip 220 and the package surface 230b of the package body 230 are aligned with (for example, flushed with) each other.

Referring to FIG. 3, FIG. 3 illustrates a diagram view of a cross-sectional view of a semiconductor device 300 according to another embodiment of the disclosure.

As illustrated in FIG. 3, the semiconductor device 300 includes at least one cage 310, at least one semiconductor chip 120, the package body 130, the first RDL 140 and at least one contact 150. The cage 310 has a first cage surface 310s1, a second cage surface 310s2 opposite to the first cage surface 310s1 and a cavity 310c extending towards the second cage surface 310s2 from the first cage surface 310s1. The semiconductor chip 120 is disposed in the cavity 310c. The package body 130 covers the semiconductor chip 120. The first RDL 140 is disposed over the package body 130 and the semiconductor chip 120. The cage 310 may constrain a displacement of the semiconductor chip 120. Furthermore, in process of manufacturing the semiconductor device 300, the semiconductor chip 120 may be placed in the cavity 310c of the cage 310 for being restricted in the cavity 310c, and accordingly it may increase the positioning accuracy of the semiconductor chip 120 and the first RDL 140.

In the present embodiment, the cage 310 may be formed of a material including organic material or inorganic material, such as metal, glass, ceramics, etc. In an embodiment, the cage 310 does not include any circuit element. The cage 310 may be formed of material the same as or similar to that of the cage 110.

In an embodiment, the cavity 310c may include the feature the same as or similar to that of the cavity 310c as aforementioned above. In the present embodiment, the cavity 310c is a through hole. For example, the cavity 310c extends to the first cage surface 310s1 from the second cage surface 310s2. In another embodiment, the cavity 310c is, for example, a blind hole.

As illustrated in FIG. 3, the package body 130 covers the first cage lateral surface 310s3 and the first cage surface 310s1 but exposes the second cage surface 310s2. In addition, the RDL lateral surface 140s of the first RDL 140 and the package lateral surface 130s of the package body 130 are exposed from the semiconductor device 300. The RDL lateral surface 140s of the first RDL 140 and the package lateral surface 130s of the package body 130 are aligned with (for example, flushed with) each other. Furthermore, in process of manufacturing the semiconductor device 300, the RDL lateral surface 140s and the package lateral surface 130s are formed by, for example, a singulation (for example, by sawing, such as diamond blade sawing or laser sawing).

Referring to FIG. 4, FIG. 4 illustrates a diagram view of a cross-sectional view of a semiconductor device 400 according to another embodiment of the disclosure.

As illustrated in FIG. 4, the semiconductor device 400 includes a cage 410, at least one semiconductor chip 120, a package body 430, the first RDL 140, at least one contact 150, a second RDL 440, at least one conductive portion 450 and a third RDL 460. The cage 410 has a first cage surface 410s1, a second cage surface 410s2 opposite to the first cage surface 410s1 and a cavity 410c extending towards the second cage surface 410s2 from the first cage surface 410s1. The semiconductor chip 120 is disposed in the cavity 410c. The package body 430 covers the semiconductor chip 120. The first RDL 140 is disposed over the package body 430 and the semiconductor chip 120. The cage 410 may constrain a displacement of the semiconductor chip 120. Furthermore, in process of manufacturing the semiconductor device 400, the semiconductor chip 120 may be placed in the cavity 410c of the cage 410 for being restricted in the cavity 410c, and accordingly it may increase the positioning accuracy of the semiconductor chip 120 and the first RDL 140.

In the present embodiment, the cage 410 may be, for example, a substrate, such as a laminate substrate, a silicon substrate, etc. The substrate may include at least one circuit element.

In the present embodiment, the cavity 410c of the cage 410 is, for example, a blind hole. Furthermore, the cavity 410c extends from the first cage surface 410s1 toward the second cage surface 410s2, but not extends to the second cage surface 410s2.

As illustrated in FIG. 4, in the present embodiment, at least a portion of the package body 430 is disposed within the cavity 410c and disposed between the lateral surface 120s of the semiconductor chip 120 and a lateral surface 410c1 of the cavity 410c. In the present embodiment, the package body 430 does not cover the first cage surface 410s1 of the cage 410. In addition, the package body 430 may be formed of a material the same as or similar to that of the package body 130. In another embodiment, the package body 430 may be formed of a material including, for example, epoxy, polyimides, silicones, polyxylylenes, soloxane polyimide, benzocyclobutene, etc.

As illustrated in FIG. 4, the first RDL 140 is disposed on and/or over the third RDL 460. The second RDL 440 is disposed on the second cage surface 410s2, and the third RDL 460 is disposed on the first cage surface 410s1 and between the first RDL 140 and the first cage surface 410s1. The second RDL 440 includes the features (for example, structures) the same as or similar to that of the first RDL 140, and the third RDL 460 includes the features (for example, structures) the same as or similar to that of the first RDL 140.

As illustrated in FIG. 4, the cage 410 has a first cage lateral surface 410s3, the first RDL 140 has the RDL lateral surface 140s, the second RDL 440 has a RDL lateral surface 440s, and the third RDL 460 has a RDL lateral surface 460s, wherein the first cage lateral surface 410s3, the RDL lateral surface 140s, the RDL lateral surface 440s and the RDL lateral surface 460s are aligned with (for example, flushed with) each other. Furthermore, in process of manufacturing the semiconductor device 400, the first cage lateral surface 410s3, the RDL lateral surface 140s, the RDL lateral surface 440s and the RDL lateral surface 460s are formed by, for example, a singulation (for example, by sawing, such as diamond blade sawing or laser sawing).

As illustrated in FIG. 4, the conductive portion 450 is electrically connects the second RDL 440 with the third RDL 460. Furthermore, the conductive portion 450 extends to the first cage surface 410s1 from the second cage surface 410s2 for electrically connecting the second RDL 440 with the third RDL 460. In an embodiment, the conductive portion 450 is, for example, a conductive via or a conductive pillar. The conductive portion 450 may be formed of a material including, for example, metal such as copper or an alloy thereof.

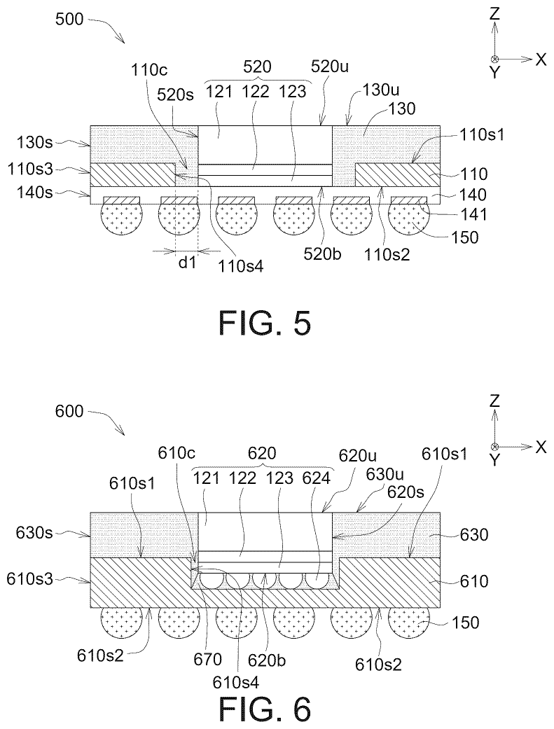

Referring to FIG. 5, FIG. 5 illustrates a diagram view of a cross-sectional view of a semiconductor device 500 according to another embodiment of the disclosure.

As illustrated in FIG. 5, the semiconductor device 500 includes at least one cage 110, at least one semiconductor chip 520, the package body 130, the first RDL 140 and at least one contact 150. The cage 110 has the first cage surface 110s1, the second cage surface 110s2 opposite to the first cage surface 110s1 and the cavity 110c extending towards the second cage surface 110s2 from the first cage surface 110s1. The semiconductor chip 520 is disposed in the cavity 110c. The package body 130 covers the semiconductor chip 520. The first RDL 140 is disposed over the package body 130 and the semiconductor chip 520. The cage 110 may constrain a displacement of the semiconductor chip 520. Furthermore, in process of manufacturing the semiconductor device 500, the semiconductor chip 520 may be placed in the cavity 110c of the cage 110 for being restricted in the cavity 110c, and accordingly it may increase the positioning accuracy of the semiconductor chip 520 and the first RDL 140.

As illustrated in FIG. 5, the cage 110 is shaped as a closed-ring. In another embodiment, the cage 110 may be shaped as an opened-ring. Viewed in a top direction, the cage 110 may be a polygonal shape (rectangle, triangle, etc.), a circle, ellipse, etc. The cage 110 has the first cage lateral surface 110s3 and the second cage lateral surface 110s4 opposite to the first cage lateral surface 110s3. A distance d1 of the second cage lateral surface 110s4 of the cage 110 and a lateral surface 520s of the semiconductor chip 520 may range between, for example, 1 micrometer and 10 micrometers, such as 1 micrometer, 2 micrometers, 3 micrometers, 4 micrometers, 5 micrometers, 6 micrometers, 7 micrometers, 8 micrometers, 9 micrometers or 10 micrometers. Such distance d1 may increase the positioning accuracy of the semiconductor chip 520 and the first RDL 140.

In the present embodiment, the cavity 110c is a through hole. Furthermore, the cavity 110c extends to the first cage surface 110s1 from the second cage surface 110s2. In another embodiment, the cavity 110c is, for example, a blind hole.

As illustrated in FIG. 5, the semiconductor chip 520 includes the base 121, the FEOL structure 122 and the BEOL structure 123. Compared to the semiconductor chip 120, the semiconductor chip 520 may omit the contact 124. The base 121 is, for example, a portion of a silicon wafer. The FEOL structure 122 is formed in and/or on the base 121, and the BEOL structure 123 is formed in and/or on the FEOL structure 122 and electrically connected with the FEOL structure 122. The BEOL structure 123 is electrically connected with the contact 150 through the first RDL 140.

As illustrated in FIG. 5, the semiconductor chip 520 has a chip surface 520b, wherein the chip surface 520b may be exposed from the cavity 110c, and the chip surface 520b of the semiconductor chip 520 and the second cage surface 110s2 of the cage 110 are, for example, aligned with (for example, flushed with) each other. In addition, the semiconductor chip 520 protrudes relative to the first cage surface 110s1 of the cage 110. In addition, the semiconductor chip 520 has a chip surface 520u opposite to the chip surface 520b, and the package body 130 has a package surface 130u, wherein the package surface 130u and the chip surface 520u are aligned with (for example, flushed with) each other. Furthermore, in process of manufacturing the semiconductor device 500, the package surface 130u and the chip surface 520u are formed by, for example, grinding, CMP (Chemical-Mechanical Planarization), etc.

As illustrated in FIG. 5, the package body 130 encapsulates the cage 110 and the semiconductor chip 520. For example, the package body 130 covers the first cage surface 110s1 and the second cage lateral surface 110s4 of the cage 110 and the lateral surface 520s of the semiconductor chip 520, but exposes the chip surface 520u of the semiconductor chip 520. In addition, the package body 130 further fills up a portion of the cavity 110c.

As illustrated in FIG. 5, the package body 130 has the package lateral surface 130s, and the package lateral surface 130s and the first cage lateral surface 110s3 are, for example, aligned with (for example, flushed with) each other. Furthermore, in process of manufacturing the semiconductor device 500, the package lateral surface 130s and the first cage lateral surface 110s3 are formed by, for example, a singulation (for example, by sawing, such as diamond blade sawing or laser sawing).

As illustrated in FIG. 5, the first RDL 140 is disposed on and/or below the package body 130 and the semiconductor chip 520. The first RDL 140 is electrically connected with the semiconductor chip 520. For example, the first RDL 140 is electrically connected with the BEOL structure 123 of the semiconductor chip 520. The first RDL 140 at least includes at least one conductive pad 141 for receiving the contact 150. In addition, the first RDL 140 has the RDL lateral surface 140s, and the RDL lateral surface 140s and the first cage lateral surface 110s3 are, for example, aligned with (for example, flushed with) each other. Furthermore, in process of manufacturing the semiconductor device 500, the RDL lateral surface 140s and the first cage lateral surface 110s3 are formed by, for example, a singulation (for example, by sawing, such as diamond blade sawing or laser sawing).

Referring to FIG. 6, FIG. 6 illustrates a diagram view of a cross-sectional view of a semiconductor device 600 according to another embodiment of the disclosure.

As illustrated in FIG. 6, the semiconductor device 600 includes at least one cage 610, at least one semiconductor chip 620, a package body 630, at least one contact 150 and an underfill 670. The cage 610 has a first cage surface 610s1, a second cage surface 610s2 opposite to the first cage surface 610s1 and has a cavity 610c extending towards the second cage surface 610s2 from the first cage surface 610s1. In the present embodiment, the cavity 610c is, for example, a blind hole. The semiconductor chip 620 is disposed in the cavity 610c. The package body 630 covers the semiconductor chip 620 and the cage 610. The cage 610 may constrain a displacement of the semiconductor chip 620. Furthermore, in process of manufacturing the semiconductor device 600, the semiconductor chip 620 may be placed in the cavity 610c of the cage 610 for being restricted in the cavity 610c, and accordingly it may increase the positioning accuracy of the semiconductor chip 620.

In the present embodiment, the cage 610 may include at least one circuit element. The cage 610 is, for example, a semiconductor substrate such as a circuit board. Alternatively, the cage 610 can be a laminate substrate, a silicon substrate, a high-thermal-conductivity substrate, a metal substrate, a combination thereof, or based on other types of material.

As illustrated in FIG. 6, the semiconductor chip 620 is a flip chip having a chip surface 620b (for example, an active surface). The semiconductor chip 620 is bonded to the cage 610 (for example, substrate) in the cavity 610c (for example, the blind hole) with the chip surface 620b facing the cavity 610c. The semiconductor chip 620 includes the base 121, the FEOL structure 122, the BEOL structure 123 and at least one contact 624. The base 121 is, for example, a portion of a silicon wafer. The FEOL structure 122 is formed in and/or on the base 121, the BEOL structure 123 is formed in and/or on the FEOL structure 122 and electrically connected with the FEOL structure 122, and the contact 624 is formed on the BEOL structure 123 and electrically connected with the BEOL structure 123. The contact 624 is disposed on and electrically connected with the chip surface 620b, and the contact 624 is, for example, a solder ball, a micro bump, a micro pillar, etc. The semiconductor chip 620 is electrically connected with the cage 610 through the contacts 624.

As illustrated in FIG. 6, the semiconductor chip 620 protrudes relative to the first cage surface 610s1 of the cage 610. In addition, the semiconductor chip 620 has a chip surface 620u, and the package body 630 has a package surface 630u, wherein the package surface 630u and the chip surface 620u are aligned with (for example, flushed with) each other. Furthermore, in process of manufacturing the semiconductor device 600, the package surface 630u and the chip surface 620u are formed by, for example, grinding, CMP, etc.

As illustrated in FIG. 6, the package body 630 encapsulates the cage 610 and the semiconductor chip 620. For example, the package body 630 covers the first cage surface 610s1 and the second cage lateral surface 610s4 of the cage 610, the lateral surface 620s of the semiconductor chip 620 and the lateral surfaces of the contact 624, but exposes the second cage surface 610s2 and the first cage lateral surface 610s3 of the cage 610. In addition, the package body 630 further fills up a portion of the cavity 610c.

As illustrated in FIG. 6, the package body 630 has a package lateral surface 630s, and the package lateral surface 630s and the first cage lateral surface 610s3 are, for example, aligned with (for example, flushed with) each other. Furthermore, in process of manufacturing the semiconductor device 600, the package lateral surface 630s and the first cage lateral surface 610s3 are formed by, for example, a singulation (for example, by sawing, such as diamond blade sawing or laser sawing).

In addition, the package body 630 may be formed of a material the same as or similar to that of the package body 130. In another embodiment, the package body 630 may be formed of a material including epoxy, polyimides, silicones, polyxylylenes, soloxane polyimide, benzocyclobutene, etc.

As illustrated in FIG. 6, the contacts 150 are disposed on the second cage surface 610s2 of the cage 610. The semiconductor device 600 is, for example, a BGA (Ball Grid Array), and the contact 150 is, for example, a solder ball (or called a BGA ball), micro bump, etc.

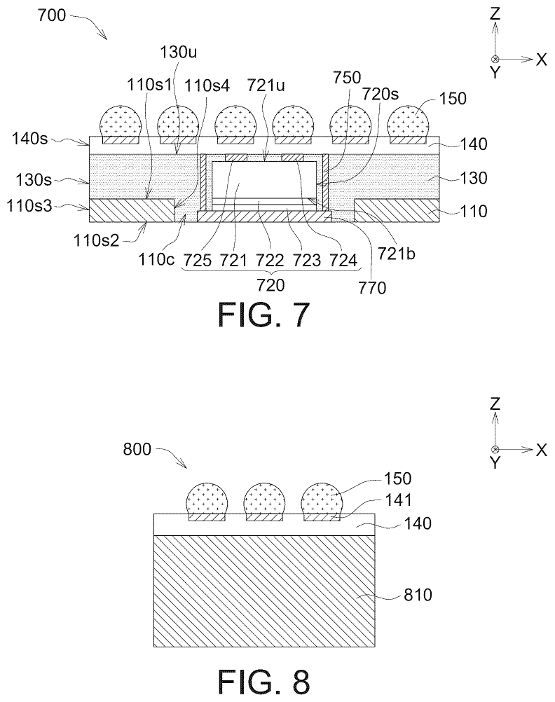

Referring to FIG. 7, FIG. 7 illustrates a diagram view of a cross-sectional view of a semiconductor device 700 according to another embodiment of the disclosure.

As illustrated in FIG. 7, the semiconductor device 700 includes at least one cage 110, at least one semiconductor chip 720, a package body 130, the first RDL 140, at least one contact 150, at least one conductive portion 750 and a conductive layer 770. The cage 110 has the first cage surface 110s1, the second cage surface 110s2 opposite to the first cage surface 110s1 and the cavity 110c extending towards the second cage surface 110s2 from the first cage surface 110s1. The semiconductor chip 720 is disposed in the cavity 110c. The package body 130 covers the semiconductor chip 720. The first RDL 140 is disposed over the package body 130 and the semiconductor chip 720. The cage 110 may constrain a displacement of the semiconductor chip 720. Furthermore, in process of manufacturing the semiconductor device 700, the semiconductor chip 720 may be placed in the cavity 110c of the cage 110 for being restricted in the cavity 110c, and accordingly it may increase the positioning accuracy of the semiconductor chip 720 and the first RDL 140.

As illustrated in FIG. 7, the semiconductor chip 720 is disposed on the conductive layer 770, and the package body 130 has a package surface 130u and a through hole extending to the conductive layer 770 from the package surface 130u. The conductive portion 750 is disposed within the through hole. In an embodiment, the conductive portion 750 is, for example, a conductive via or a conductive pillar. The conductive portion 750 may be formed of a material including, for example, metal such as copper or an alloy thereof. The conductive layer 770 may be formed of a material including, for example, metal such as copper or an alloy thereof.

As illustrated in FIG. 7, in the present embodiment, the semiconductor chip 720 is, for example, a transistor. The semiconductor chip 720 includes a base 721, an electrode 722, a solder 723 and a plurality of electrodes 724 and 725. The base 721 is, for example, a portion of a silicon wafer. Although not illustrated, the base 121 includes at least one transistor circuit. The electrode 722 is formed in and/or on a first surface 721b of the base 721, the solder 723 is formed in and/or on the electrode 722 and electrically connected with the electrode 722. The semiconductor chip 720 is disposed on the conductive layer 770 through the solder 723. The transistor circuit in the base 721 is electrically connected with the conductive layer 770 through the electrode 722 and the solder 723, and electrically connected with the first RDL 140 through the electrodes 724 and 725. The electrode 724 and the electrode 725 are formed on a second surface 721u of the base 721 and electrically connected with the first RDL 140.

As illustrated in FIG. 7, the cage 110 is shaped as a closed-ring. In another embodiment, the cage 110 may be shaped as an opened-ring. Viewed in a top direction, the cage 110 may be a polygonal shape (rectangle, triangle, etc.), a circle, ellipse, etc. The cage 110 has the first cage lateral surface 110s3 and the second cage lateral surface 110s4 opposite to the first cage lateral surface 110s3.

In the present embodiment, the cavity 110c is a through hole. Furthermore, the cavity 110c extends to the first cage surface 110s1 from the second cage surface 110s2. In another embodiment, the cavity 110c is, for example, a blind hole.

As illustrated in FIG. 7, the package body 130 encapsulates the cage 110 and the semiconductor chip 720. For example, the package body 130 covers the first cage surface 110s1 and the second cage lateral surface 110s4 of the cage 110 and a lateral surface 720s of the semiconductor chip 720. In addition, the package body 130 further fills up a portion of the cavity 110c.

As illustrated in FIG. 7, the package body 130 has a package lateral surface 130s, and the package lateral surface 130s and the first cage lateral surface 110s3 are, for example, aligned with (for example, flushed with) each other. Furthermore, in process of manufacturing the semiconductor device 700, the package lateral surface 130s and the first cage lateral surface 110s3 are formed by, for example, a singulation (for example, by sawing, such as diamond blade sawing or laser sawing).

As illustrated in FIG. 7, the first RDL 140 has the RDL lateral surface 140s, wherein the RDL lateral surface 140s and the first cage lateral surface 110s3 are, for example, aligned with (for example, flushed with) each other. Furthermore, in process of manufacturing the semiconductor device 700, the RDL lateral surface 140s and the first cage lateral surface 110s3 are formed by, for example, a singulation (for example, by sawing, such as diamond blade sawing or laser sawing).

As described above, any one of the semiconductor devices 100 to 700 is, for example, a fan-out structure, such as a FOWLP (fan-out wafer-level packaging). The FOWLP can be used for a wide variety of applications including application processor for mobiles (e.g., smart phones) and wearables (e.g., smart watches), PMIC, RF, 5G antenna-in-package (AiP), audio codec, automotive radar, and high-performance computing and data centers (HPC). The advantages of FOWLP include a thinner, smaller-form-factor package, higher-I/O density, improved RF performance and lower thermal resistance compared with conventional flip chip packaging. However, in another embodiment, the semiconductor device may be designed as a fan-in structure.

Referring to FIG. 8, FIG. 8 illustrates a diagram view of a semiconductor device 800 (fan-in structure) according to an embodiment of the disclosure.

As illustrated in FIG. 8, the semiconductor device 800 includes a substrate 810, the RDL 140 and at least one contact 150. The substrate 810 is, for example, a semiconductor substrate which includes at least one semiconductor circuit. The RDL 140 is disposed on the substrate 810 and includes at least one conductive pad 141. The contacts 150 are disposed on the first RDL 140. The semiconductor device 800 is, for example, a BGA (Ball Grid Array), and the contact 150 is, for example, a solder ball (or called a BGA ball), micro bump, etc.

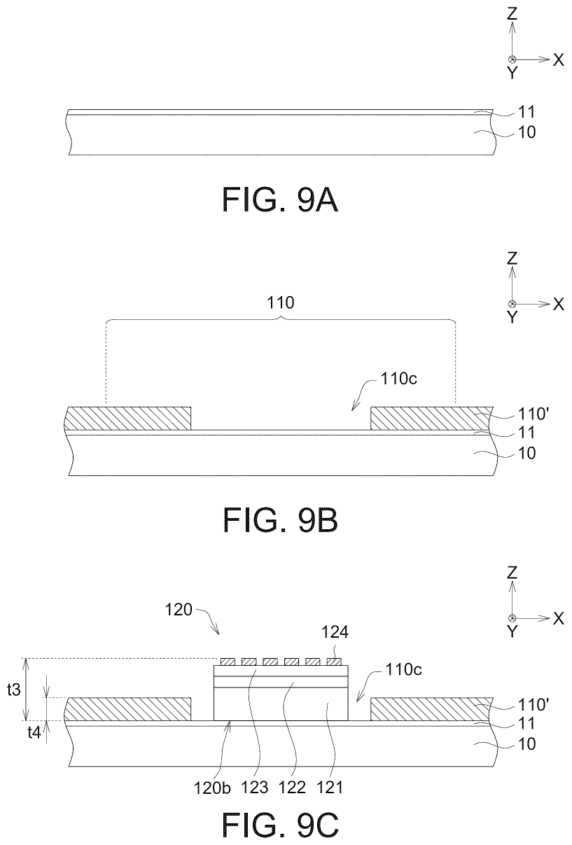

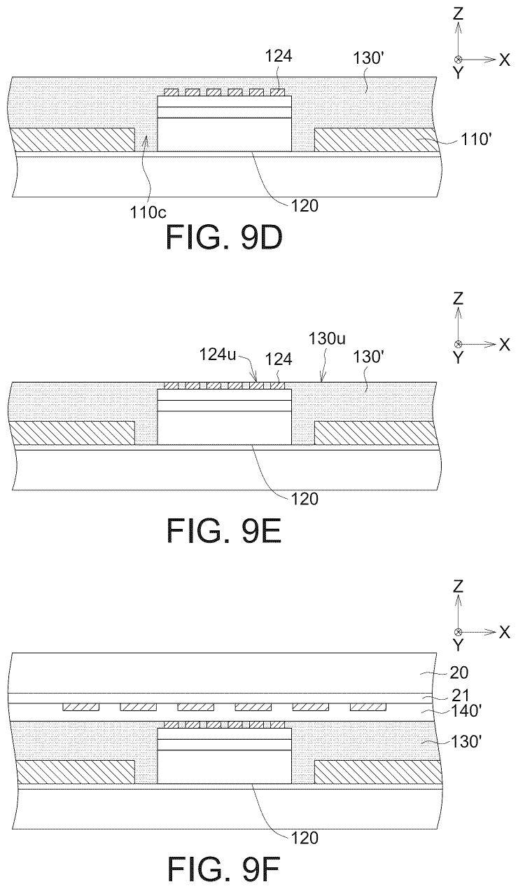

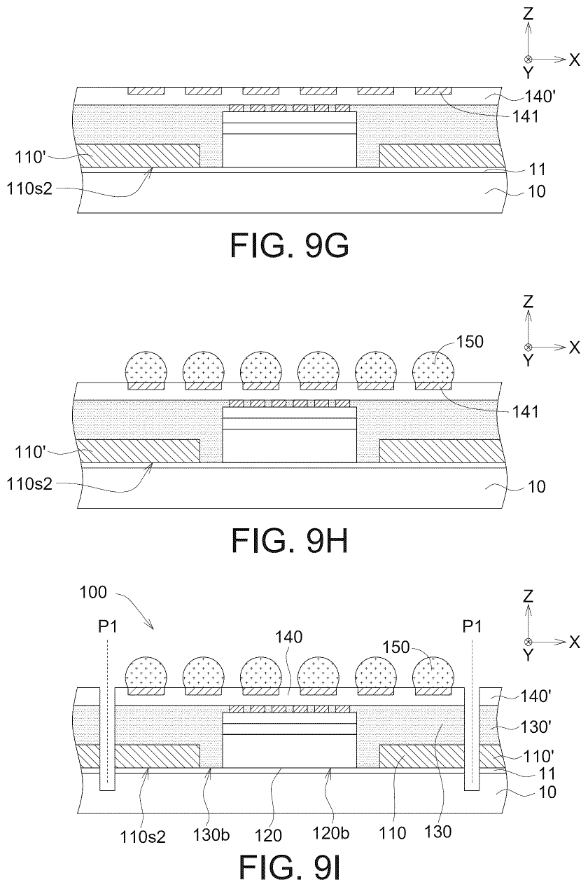

Referring to FIGS. 9A to 9I, FIGS. 9A to 9I illustrate schematic diagrams of manufacturing method of the semiconductor device 100 in FIG. 1B according to an embodiment.

As illustrated in FIG. 9A, a carrier 10 on which a release layer 11 is disposed is provided. In an embodiment, the release layer 11 is formed on the carrier 10 by using, for example, deposition. The carrier 10 can be based on glass, IC substrate, metal or a suitable material with a sufficient thickness to minimize warpage.

As illustrated in FIG. 9B, a cage plate 110′ is disposed on the carrier 10 through the release layer 11. The cage plate 110′ includes at least one cage 110 each having the cavity 110c. When the cage plate 110′ includes a plurality of the cages 110, the cages 110 are connected with each other. The cage 110 may be divided by using, for example, singulation in subsequent process. The cage 110 can be a thin, laminated photoresist. In an embodiment, the cage plate 110′ may be formed by using, deposition, etc., wherein the deposition includes printing, coating, etc. In addition, the cage 110′ may have a thickness ranging between, for example, 200 micrometers and 300 micrometers.

As illustrated in FIG. 9C, at least one semiconductor chip 120 is disposed on the carrier 10 through the release layer 11. Each semiconductor chip 120 is disposed in the corresponding cavity 110c of the cage plate 110′. The semiconductor chip 120 includes the base 121, the FEOL structure 122, the BEOL structure 123 and at least one contact 124. The base 121 is, for example, a portion of a silicon wafer. The FEOL structure 122 is formed in and/or on the base 121, the BEOL structure 123 is formed in and/or on the FEOL structure 122 and electrically connected with the FEOL structure 122, and the contact 124 is formed on the BEOL structure 123 and electrically connected with the BEOL structure 123. The contact 124 is, for example, a solder ball, a micro bump, a micro pillar, etc. The base 121 has the chip surface 120b, wherein the chip surface 120b of the base 121 is disposed on the carrier 10 through the release layer 11. In addition, the semiconductor chip 120 has a thickness t3 greater than a thickness t4 of the cage plate 110′.

As illustrated in FIG. 9D, a package body material 130′ covering the semiconductor chip 120 and the cage plate 110′ is formed by using, for example, transfer molding, compression molding, etc. The package body material 130′ covers the lateral surfaces of the semiconductor chip 120 and fills up a portion of the cavity 110c.

As illustrated in FIG. 9E, a portion of the package body material 130′ in FIG. 9D is removed by using, for example, grinding, CMP, etc. After removing, a contact surface 124u of the contact 124 of the semiconductor chip 120 and the package surface 130u of the package body material 130′ are formed, wherein the contact surface 124u and the package surface 130u are aligned with (for example, flushed with) each other.

As illustrated in FIG. 9F, the first RDL structure 140′ on a carrier 20 is transferred to the semiconductor chip 120 and the package body material 130′ in FIG. 9E. Before transferring, the first RDL structure 140′ may be pre-formed on the carrier 20 by using, for example, at least one semiconductor process. In an embodiment, the first RDL structure 140′ may be formed on a release layer 21 which is disposed on the carrier 20.

As illustrated in FIG. 9G, the carrier 20 with the release layer 21 in FIG. 9F is removed from the first RDL structure 140′, wherein the conductive pad 141 of the first RDL structure 140′ is exposed.

As illustrated in FIG. 9H, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 9I, at least one singulation passage P1 passing through the first RDL structure 140′, the cage plate 110′, the package body material 130′ and a portion of the carrier 10 is formed to form at least one semiconductor device 100 by using, for example, sawing (such as diamond blade sawing or laser sawing), etc. After singulation, the cage plate 110′ forms at least one cage 110, the first RDL structure 140′ forms at least one first RDL 140, the package body material 130′ forms at least one package body 130. After singulation, each semiconductor device 100 includes the cage 110, at least one semiconductor chip 120, the package body 130, the first RDL 140 and at least one contact 150.

Then, the semiconductor device 100 is separated from the release layer 11 and the carrier 10 in FIG. 9I. After separated, the second cage surface 110s2 of the cage 110, the chip surface 120b of the semiconductor chip 120 and a package surface 130b of the package body 130 of the semiconductor device 100 are exposed.

In another embodiment, the carrier 10 and the release layer 11 in FIG. 9G may be replaced by a tape (not illustrated), then at least one contact 150 is formed on the conductive pad 141 of the first RDL structure 140′ (as illustrated in FIG. 9H), and then at least one singulation passage P1 passing through the first RDL structure 140′, the cage plate 110′, the package body material 130′ and a portion of the tape is formed to form at least one semiconductor device 100 by using, for example, sawing (such as diamond blade sawing or laser sawing), etc. (as illustrated in FIG. 9I). In addition, the manufacturing method of the semiconductor device in other embodiment includes the singulation processes the same as or similar to that of the manufacturing method of the semiconductor device 10, and they will not repeated here.

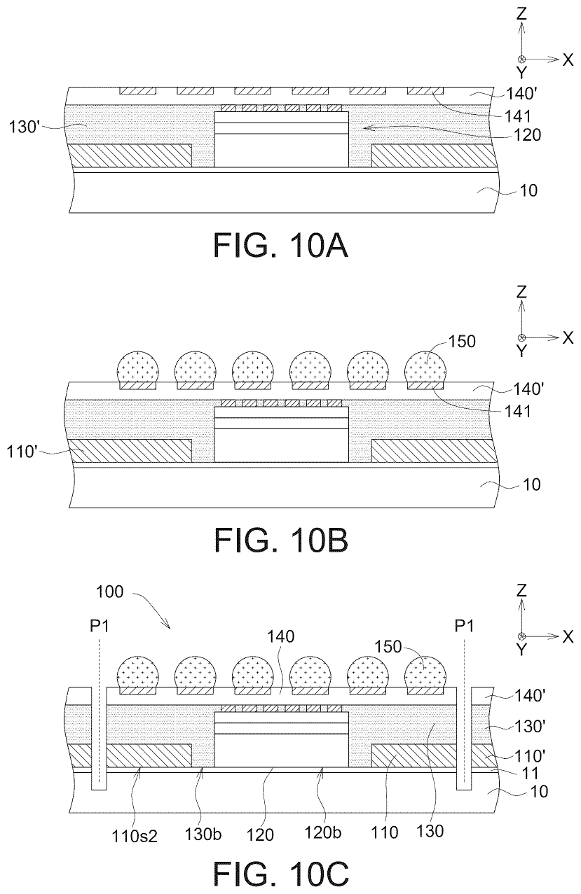

Referring to FIGS. 10A to 10C, FIGS. 10A to 10C illustrate schematic diagrams of manufacturing method of the semiconductor device 100 in FIG. 1B according to another embodiment.

As illustrated in FIG. 10A, after step in FIG. 9E, the first RDL structure 140′ is formed on the package body material 130′ and the semiconductor chip 120 by using, for example, plating, lithography, deposition, etching, etc. The conductive pad 141 of the first RDL structure 140′ is exposed and faces up. In the present embodiment, the first RDL structure 140′ is formed by a process other than transferring. In other words, the first RDL structure 140′ is directly formed on the package body material 130′ and the semiconductor chip 120 without the carrier 20.

As illustrated in FIG. 10B, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 10C, at least one singulation passage P1 passing through the first RDL structure 140′, the cage plate 110′, the package body material 130′ and a portion of the carrier 10 is formed to form at least one semiconductor device 100 by using, for example, sawing (such as diamond blade sawing or laser sawing), etc. After singulation, the cage plate 110′ forms at least one cage 110, the first RDL structure 140′ forms at least one first RDL 140, the package body material 130′ forms at least one package body 130. After singulation, each semiconductor device 100 includes the cage 110, at least one semiconductor chip 120, the package body 130, the first RDL 140 and at least one contact 150.

Then, the semiconductor device 100 is separated from the release layer 11 and the carrier 10 in FIG. 10C. After separated, the second cage surface 110s2 of the cage 110, the chip surface 120b of the semiconductor chip 120 and the package surface 130b of the package body 130 of the semiconductor device 100 are exposed.

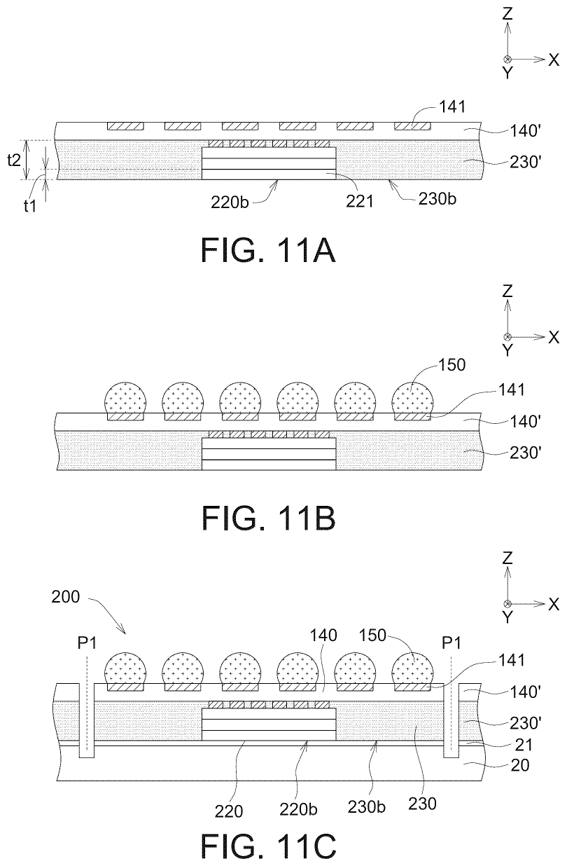

Referring to FIGS. 11A to 11C, FIGS. 11A to 11C illustrate schematic diagrams of manufacturing method of the semiconductor device 200 in FIG. 2 according to an embodiment.

As illustrated in FIG. 11A, after step in FIG. 10A, the cage plate 110′, a portion (for example, the base 121) of the semiconductor chip 120 and a portion of the package body material 130′ in FIG. 10A is removed by using, for example, grinding, CMP, etc. After removing, the base 121 in FIG. 10A is thinned to form the base 221 which has the thickness t1, and the package body material 130′ in FIG. 10A is thinned to form the package body material 230′ which has the thickness t2. After removing, the package body material 230′ forms the package surface 230b, and the base 121 of the semiconductor chip 220 forms the chip surface 220b, wherein the chip surface 220b of the semiconductor chip 220 and the package surface 230b of the package body 230 are aligned with (for example, flushed with) each other.

As illustrated in FIG. 11B, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 11C, the structure in FIG. 11B is disposed on a carrier 20 through a release layer 21. Then, at least one singulation passage P1 passing through the first RDL structure 140′, the package body material 230′ and a portion of the carrier 20 is formed to form at least one semiconductor device 200 by using, for example, sawing (such as diamond blade sawing or laser sawing), etc. After singulation, the first RDL structure 140′ forms at least one first RDL 140, and the package body material 230′ forms at least one package body 230. After singulation, each semiconductor device 200 includes at least one semiconductor chip 220, the package body 230, the first RDL 140 and at least one contact 150. In an embodiment, the carrier 20 is, for example, a tape.

Then, the semiconductor device 200 is separated from the release layer 21 and the carrier 20 in FIG. 11C. After separated, the chip surface 220b of the semiconductor chip 220 and the package surface 230b of the package body 230 are exposed.

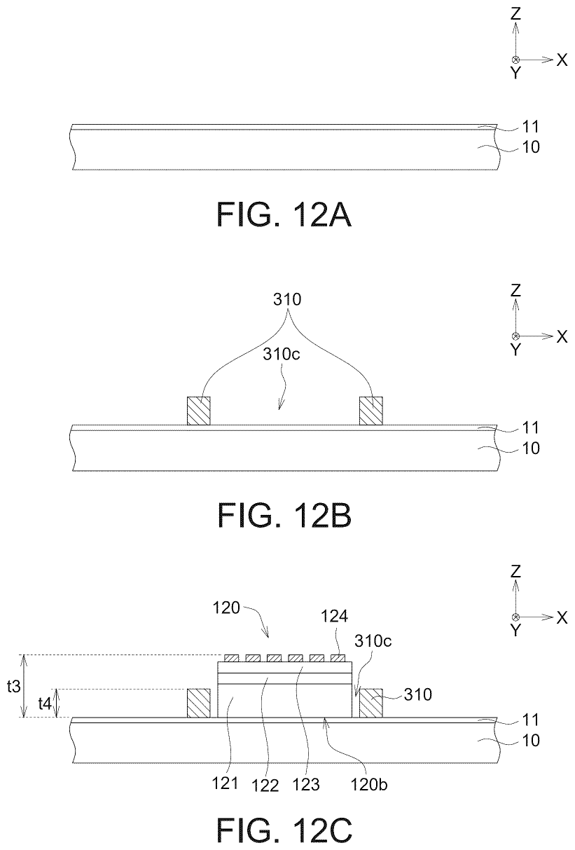

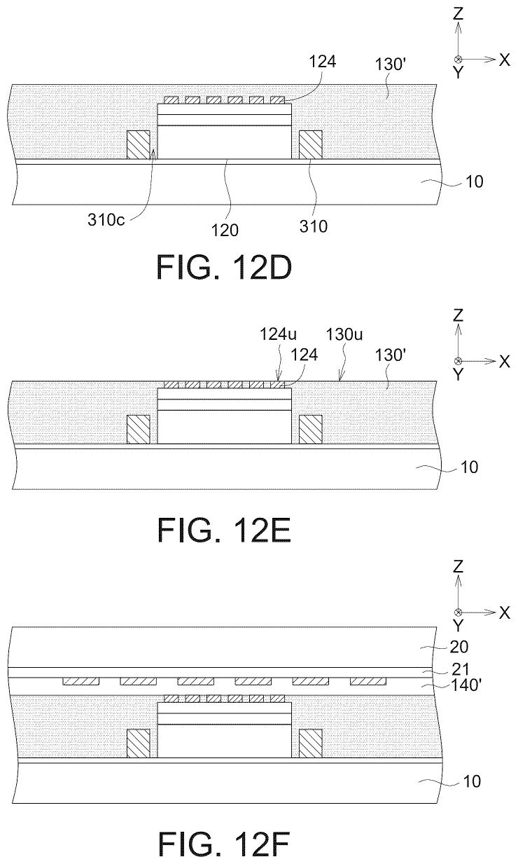

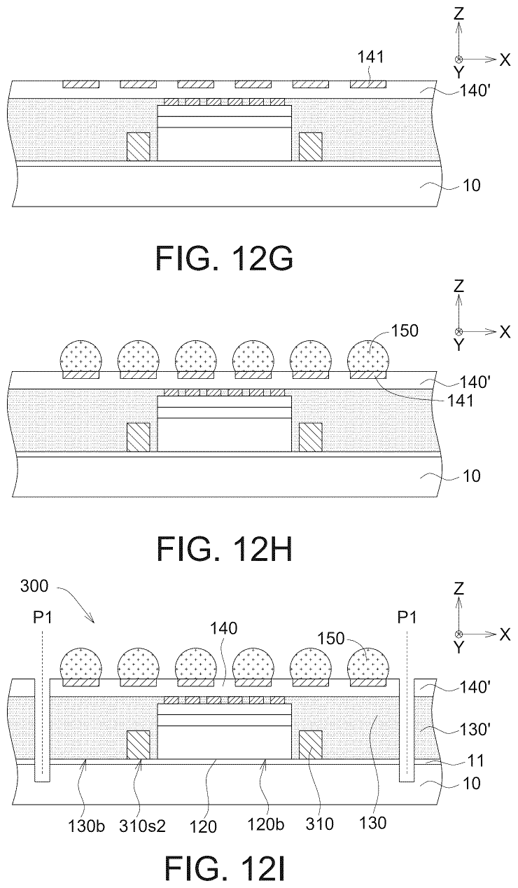

Referring to FIGS. 12A to 121, FIGS. 12A to 121 illustrate schematic diagrams of manufacturing method of the semiconductor device 300 in FIG. 3 according to an embodiment.

As illustrated in FIG. 12A, the carrier 10 on which the release layer 11 is disposed is provided. In an embodiment, the release layer 11 is formed on the carrier 10 by using, for example, deposition.

As illustrated in FIG. 12B, at least one cage 310 is disposed on the carrier 10 through the release layer 11. Each cage 310 has the cavity 310c. The cage 310 can be a metal, organic or inorganic stopper.

As illustrated in FIG. 12C, at least one semiconductor chip 120 is disposed on the carrier 10 through the release layer 11. Each semiconductor chip 120 is disposed in the corresponding cavity 310c of the cage 310. The semiconductor chip 120 includes the base 121, the FEOL structure 122, the BEOL structure 123 and at least one contact 124. The base 121 is, for example, a portion of a silicon wafer. The FEOL structure 122 is formed in and/or on the base 121, the BEOL structure 123 is formed in and/or on the FEOL structure 122 and electrically connected with the FEOL structure 122, and the contact 124 is formed on the BEOL structure 123 and electrically connected with the BEOL structure 123. The contact 124 is, for example, a solder ball, a micro bump, a micro pillar, etc. The base 121 has the chip surface 120b, wherein the chip surface 120b of the base 121 is disposed on the carrier 10 through the release layer 11. In addition, the semiconductor chip 120 has the thickness t3 greater than the thickness t4 of the cage 310.

As illustrated in FIG. 12D, a package body material 130′ covering the semiconductor chip 120 and the cage 310 is formed by using, for example, transfer molding, compression molding, etc. The package body material 130′ fills up a portion of the cavity 310c.

As illustrated in FIG. 12E, a portion of the package body material 130′ is removed by using, for example, grinding, CMP, etc. After removing, the contact surface 124u of the contact 124 of the semiconductor chip 120 and the package surface 130u of the package body material 130′ are formed, wherein the contact surface 124u and the package surface 130u are aligned with (for example, flushed with) each other.

As illustrated in FIG. 12F, the first RDL structure 140′ on a carrier 20 is transferred to the semiconductor chip 120 and the package body material 130′ in FIG. 12E. Before transferring, the first RDL structure 140′ may be pre-formed on the carrier 20 by using, for example, at least one semiconductor process. In an embodiment, the first RDL structure 140′ may be formed on the release layer 21 which is disposed on the carrier 20.

As illustrated in FIG. 12G, the carrier 20 with the release layer 21 in FIG. 12F is removed from the first RDL structure 140′, wherein the conductive pad 141 of the first RDL structure 140′ is exposed.

As illustrated in FIG. 12H, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 12I, at least one singulation passage P1 passing through the first RDL structure 140′, the package body material 130′ and a portion of the carrier 10 is formed to form at least one semiconductor device 300 by using, for example, sawing (such as diamond blade sawing or laser sawing), etc. After singulation, the first RDL structure 140′ forms at least one first RDL 140, the package body material 130′ forms at least one package body 130. After singulation, each semiconductor device 300 includes the cage 310, at least one semiconductor chip 120, the package body 130, the first RDL 140 and at least one contact 150.

Then, the semiconductor device 300 is separated from the release layer 11 and the carrier 10 in FIG. 12I. After separated, the chip surface 120b of the semiconductor chip 120, the second cage surface 310s2 of the cage 310 and the package surface 130b of the package body 130 in FIG. 12I are exposed.

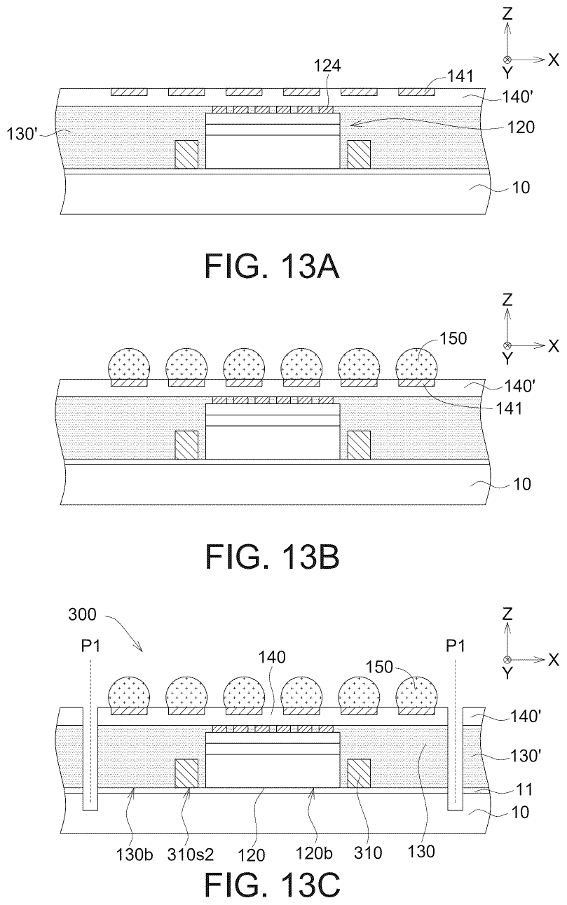

Referring to FIGS. 13A to 13C, FIGS. 13A to 13C illustrate schematic diagrams of manufacturing method of the semiconductor device 300 in FIG. 3 according to another embodiment.

As illustrated in FIG. 13A, after step in FIG. 12E, the first RDL structure 140′ is formed on the package body material 130′ and the semiconductor chip 120 by using, for example, deposition, lithography, etching, plating, etc. The conductive pad 141 of the first RDL 140 is exposed and faces up. In the present embodiment, the first RDL structure 140′ is formed by a process other than transferring. In other words, the first RDL structure 140′ is directly formed on the package body material 130′ and the semiconductor chip 120 without the carrier 20.

As illustrated in FIG. 13B, the contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 13C, at least one singulation passage P1 passing through the first RDL structure 140′, the package body material 130′ and a portion of the carrier 10 is formed to form at least one semiconductor device 300 by using, for example, sawing (such as diamond blade sawing or laser sawing), etc. After singulation, the first RDL structure 140′ forms at least one first RDL 140, and the package body material 130′ forms at least one package body 130. After singulation, each semiconductor device 300 includes the cage 310, at least one semiconductor chip 120, the package body 130, the first RDL 140 and at least one contact 150.

Then, the semiconductor device 300 is separated from the release layer 11 and the carrier 10 in FIG. 13C. After separated, the chip surface 120b of the semiconductor chip 120, the second cage surface 310s2 of the cage 310 and the package surface 130b of the package body 130 in FIG. 13C are exposed.

In another embodiment, after step in FIG. 13A, the semiconductor device 300 may be formed by using manufacture processes the same as or similar to steps in FIG. 11A to 11C.

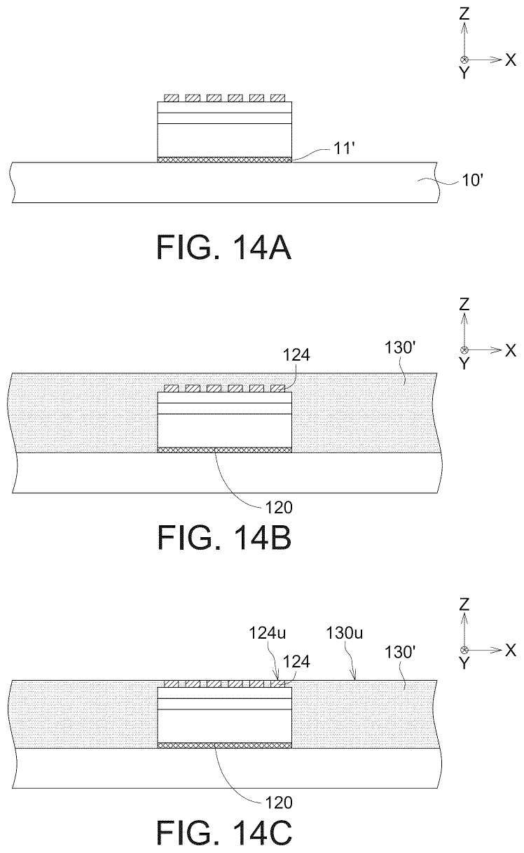

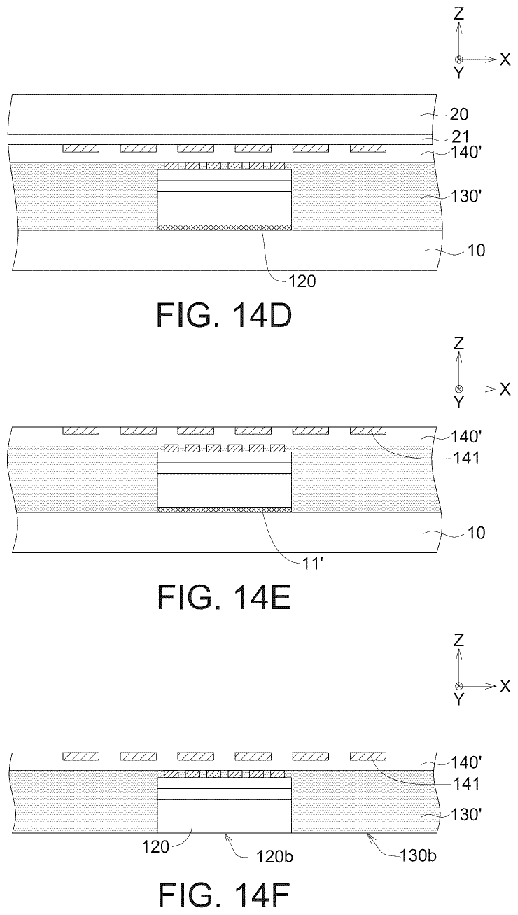

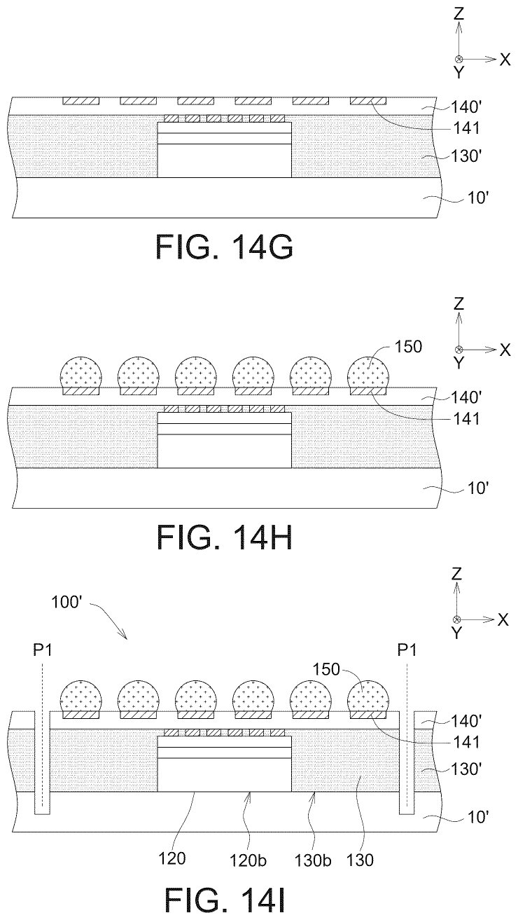

Referring to FIGS. 14A to 14I, FIGS. 14A to 14I illustrate schematic diagrams of manufacturing method of a semiconductor device 100′ according to another embodiment.

As illustrated in FIG. 14A, at least one semiconductor chip 120 is bonded to the carrier 10′ through a bonding layer 11′, wherein the bonding layer 11′ is formed by using, for example, anodic treatment.

As illustrated in FIG. 14B, the package body material 130′ covering the semiconductor chip 120 is formed on the carrier 10′ by using, for example, transfer molding, compression molding, etc.

As illustrated in FIG. 14C, a portion of the package body material 130′ in FIG. 14B is removed by using, for example, grinding, CMP, etc. After removing, the contact surface 124u of the contact 124 of the semiconductor chip 120 and the package surface 130u of the package body material 130′ are formed, wherein the contact surface 124u and the package surface 130u are aligned with (for example, flushed with) each other.

As illustrated in FIG. 14D, the first RDL structure 140′ on the carrier 20 is transferred to the semiconductor chip 120 and the package body material 130′ in FIG. 14C. Before transferring, the first RDL structure 140′ may be pre-formed on the carrier 20 by using, for example, at least one semiconductor process. In an embodiment, the first RDL structure 140′ may be formed on the release layer 21 which is disposed on the carrier 20.

As illustrated in FIG. 14E, the carrier 20 with the release layer 21 in FIG. 14D is removed from the first RDL structure 140′, wherein the conductive pad 141 of the first RDL structure 140′ is exposed.

As illustrated in FIG. 14F, the carrier 10 and the bonding layer 11′ in FIG. 14E are removed by using, for example, wet etching, back-grinding, chemical-mechanical polishing, dry etching (e.g., reactive ion etching) or a combination thereof. After removing, the chip surface 120b of the semiconductor chip 120 and the package surface 130b of the package body material 130′ are formed, wherein the chip surface 120b and the package surface 130b may aligned with (for example, flushed with) each other.

As illustrated in FIG. 14G, the structure in FIG. 14F is disposed on a carrier 10′, for example, an adhesion tape.

As illustrated in FIG. 14H, the contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 14I, at least one singulation passage P1 passing through the first RDL structure 140′, the package body material 130′ and a portion of the carrier 10′ is formed to form at least one semiconductor device 100′ by using, for example, sawing (such as diamond blade sawing or laser sawing), etc. After singulation, the first RDL structure 140′ forms at least one first RDL 140, and the package body material 130′ forms at least one package body 130. After singulation, each semiconductor device 100′ includes the semiconductor chip 120, the package body 130, the first RDL 140 and at least one contact 150.

Then, the semiconductor device 100′ is separated from the carrier 10′ in FIG. 14I. After separated, the chip surface 120b of the semiconductor chip 120 and the package surface 130b of the package body 130 in FIG. 14I are exposed.

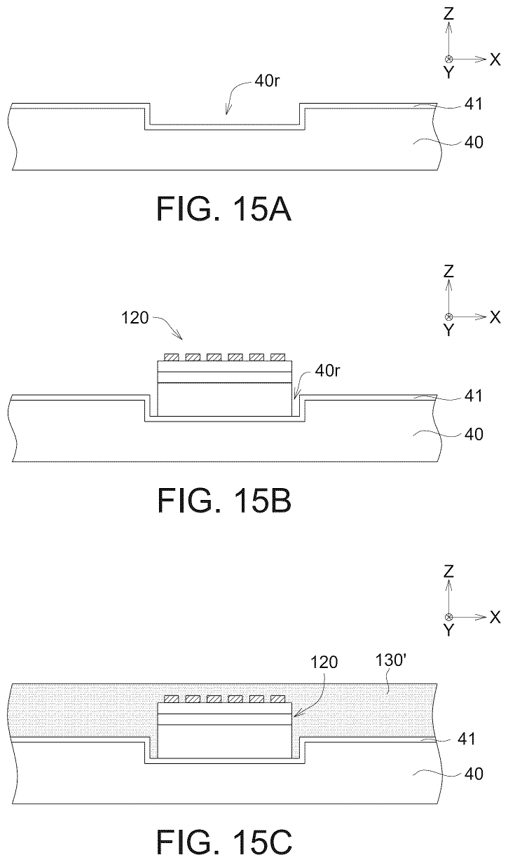

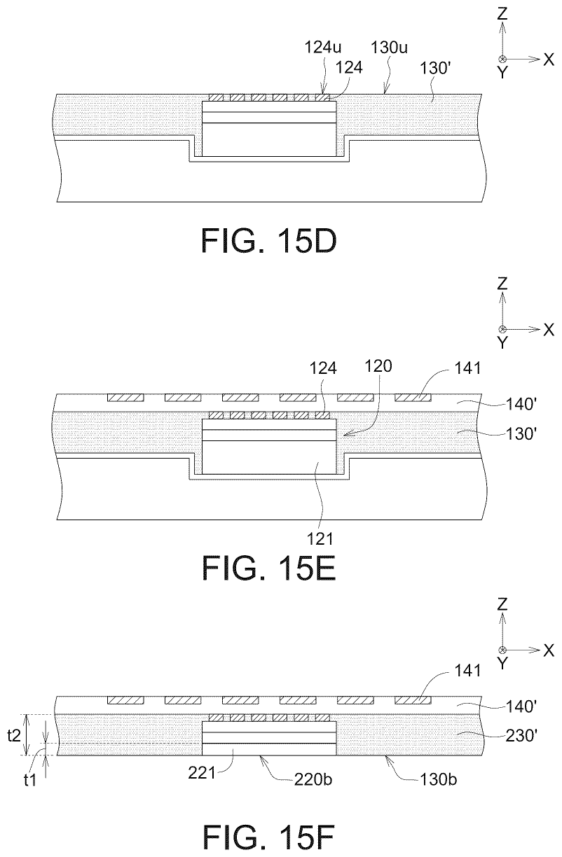

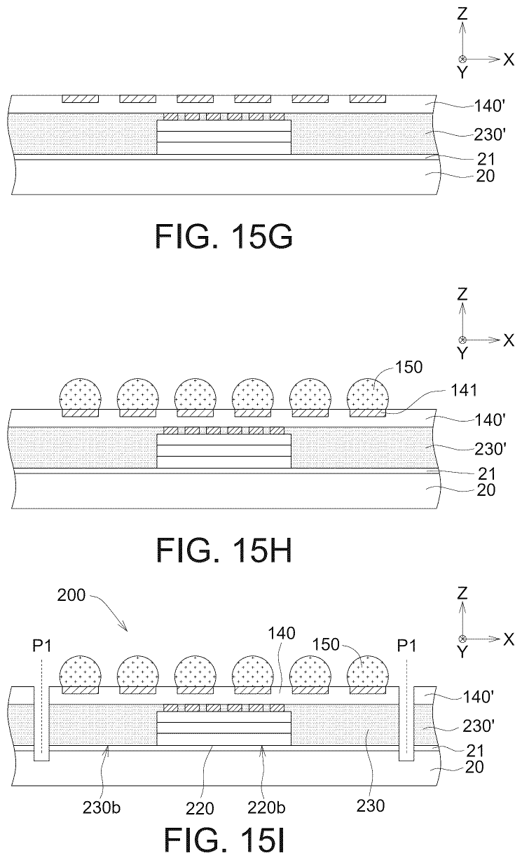

Referring to FIGS. 15A to 15I, FIGS. 15A to 15I illustrate schematic diagrams of manufacturing method of the semiconductor device 200 in FIG. 2 according to another embodiment.

As illustrated in FIG. 15A, a carrier 40 on which a release layer 41 is disposed is provided. In an embodiment, the release layer 41 is formed on the carrier 40 by using, for example, deposition. The carrier 40 has a cavity 40r, wherein the release layer 41 is further formed on at least one of all sidewalls of the recess 40r.

As illustrated in FIG. 15B, at least one semiconductor chip 120 is disposed on the carrier 40 through the release layer 41, wherein the semiconductor chip 120 is disposed in the cavity 40r of the carrier 40. The cavity 40r of the carrier 40 may constrain a displacement of the semiconductor chip 120. Furthermore, the semiconductor chip 120 may be placed in the cavity 40r of the carrier 40 for being restricted in the cavity 40r.

As illustrated in FIG. 15C, the package body material 130′ covering the semiconductor chip 120 and the carrier 40 is formed by using, for example, transfer molding, compression molding, etc. The package body material 130′ fills up a portion of the cavity 40r, and accordingly it may increase the positioning accuracy of the semiconductor chip 120 and the first RDL structure 140′ (the first RDL structure 140′ is formed in the process of FIG. 15E).

As illustrated in FIG. 15D, a portion of the package body material 130′ in FIG. 15C is removed by using, for example, grinding, CMP, etc. After removing, the contact surface 124u of the contact 124 of the semiconductor chip 120 and the package surface 130u of the package body material 130′ are formed, wherein the contact surface 124u and the package surface 130u are aligned with (for example, flushed with) each other.

As illustrated in FIG. 15E, the first RDL structure 140′ over the package body material 130′ and the semiconductor chip 120 is formed by using, for example, at least one semiconductor process. The first RDL structure 140′ includes at least one conductive pad 141 which is exposed and faces up.

As illustrated in FIG. 15F, a portion of the base 121 and the entirety of the carrier 40 in FIG. 15E are removed by using, for example, grinding, CMP, etc. After removing, the base 121 in FIG. 15E is thinned to form the base 221 which has the thickness t1, and the package body material 130′ in FIG. 15E is thinned to form the package body material 230′ which has the thickness t2.

As illustrated in FIG. 15G, the structure in FIG. 15F is disposed on the carrier 20 through the release layer 21.

As illustrated in FIG. 15H, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 15I, at least one singulation passage P1 passing through the first RDL structure 140′, the package body material 230′ and a portion of the carrier 20 is formed to form at least one semiconductor device 200 by using, for example, sawing (such as diamond blade sawing or laser sawing), etc. After singulation, the first RDL structure 140′ forms at least one first RDL 140, and the package body material 230′ forms at least one package body 230. After singulation, each semiconductor device 200 includes at least one semiconductor chip 220, the package body 230, the first RDL 140 and at least one contact 150.

Then, the semiconductor device 200 is separated from the release layer 21 and the carrier 20 in FIG. 15I. After separated, the chip surface 220b of the semiconductor chip 220 and the package surface 230b of the package body 230 are exposed.

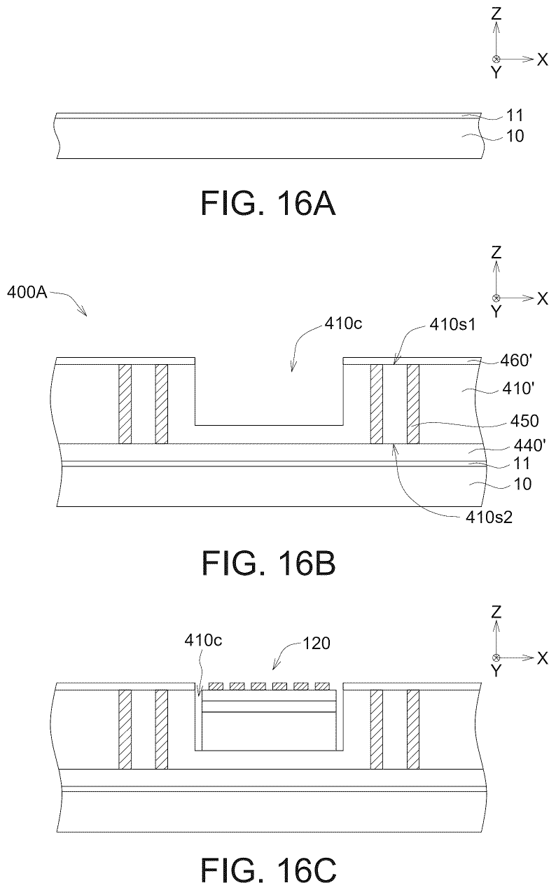

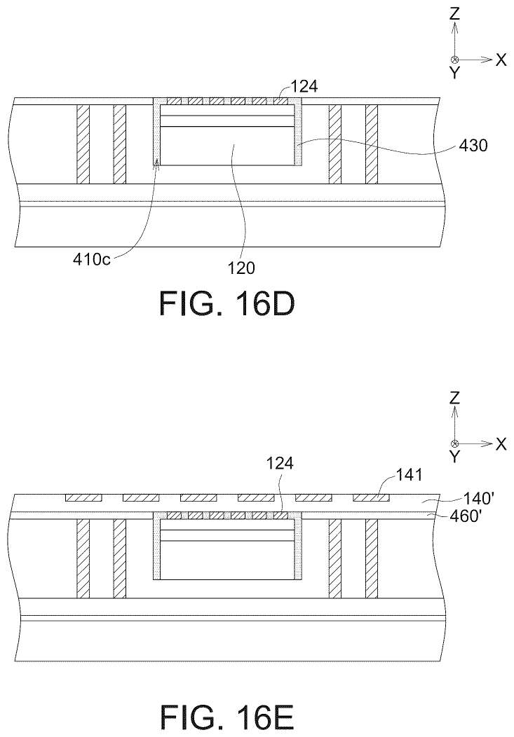

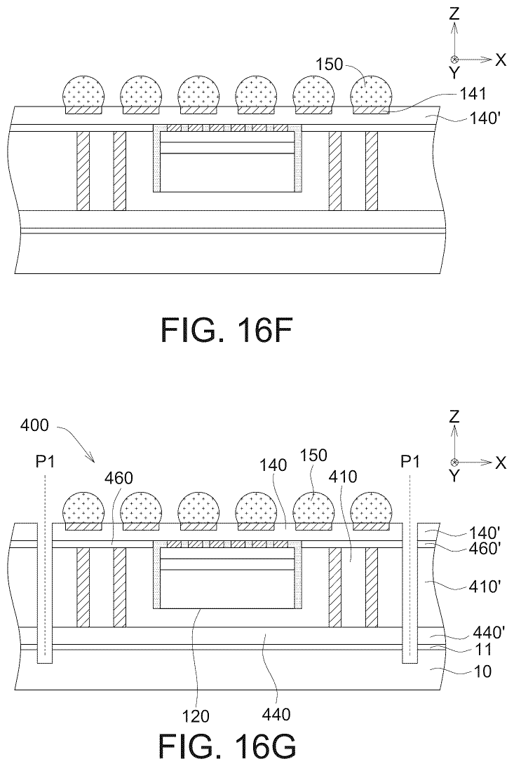

Referring to FIGS. 16A to 16G, FIGS. 16A to 16G illustrate schematic diagrams of manufacturing method of the semiconductor device 400 in FIG. 4 according to an embodiment.

As illustrated in FIG. 16A, the carrier 10 on which the release layer 11 is disposed is provided. In an embodiment, the release layer 11 is formed on the carrier 10 by using, for example, deposition.

As illustrated in FIG. 16B, a semiconductor component 400A is disposed on the carrier 10 through the release layer 11. The semiconductor component 400A includes a cage plate 410′, a second RDL structure 440′, at least one conductive portion 450 and the third RDL structure 460′. The cage plate 410′ has the first cage surface 410s1, the second cage surface 410s2 opposite to the first cage surface 410s1 and has at least one cavity 410c extending towards the second cage surface 410s2 from the first cage surface 410s1. In the present embodiment, the cavity 410c is, for example, blind hole. The cage 410′ can be a laminated substrate, s silicon substrate, a high-thermal-conductivity substrate, a metal substrate, a combination thereof, or based on other types of material. The conductive portion 450 is electrically connects the second RDL structure 440′ with the third RDL structure 460′. Furthermore, the conductive portion 450 extends to the first cage surface 410s1 from the second cage surface 410s2 for electrically connecting the second RDL structure 440′ with the third RDL structure 460′.

As illustrated in FIG. 16C, at least one semiconductor chip 120 is disposed in the corresponding cavity 410c. The cage plate 410′ may constrain a displacement of the semiconductor chip 120. Furthermore, the semiconductor chip 120 may be placed in the cavity 410c of the cage plate 410′ for being restricted in the cavity 410c, and accordingly it may increase the positioning accuracy of the semiconductor chip 120 and the first RDL structure 140′ (the first RDL structure 140′ is formed in the process of FIG. 16E).

As illustrated in FIG. 16D, the package body 430 filling up the cavity 410c is formed by using, for example, glue dispense, transfer molding, or compression molding, etc. In another embodiment, if necessary, a portion of the package body 430 may be removed to expose the contacts 124 of the semiconductor chip 120 by using, for example, grinding, CMP, etc.

As illustrated in FIG. 16E, a the first RDL structure 140′ over the third RDL structure 460′ and the contacts 124 of the semiconductor chip 120 is formed by using, for example, plating, lithography, deposition, etching, etc. The first RDL structure 140′ at least includes at least one conductive pad 141 exposed from the first RDL structure 140′. In another embodiment, the first RDL structure 140′ may be formed by using, for example, transferring method as illustrated in FIG. 9F.

As illustrated in FIG. 16F, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 16G, at least one singulation passage P1 passing through the first RDL structure 140′, the third RDL structure 460′, the cage plate 410′, the second RDL structure 440′ and a portion of the carrier 10 is formed to form at least one semiconductor device 400 by using, for example, sawing (such as diamond blade sawing or laser sawing), etc. After singulation, the cage plate 410′ forms at least one cage 410, the first RDL structure 140′ forms at least one first RDL 140, the third RDL structure 460′ forms at least one third RDL 460, and the second RDL structure 440′ forms at least one second RDL 440. After singulation, each semiconductor device 400 includes the cage 410, at least one semiconductor chip 120, the package body 430, the first RDL 140, at least one contact 150, the second RDL 440, at least one conductive portion 450 and the third RDL 460.

Then, the semiconductor device 400 is separated from the release layer 11 and the carrier 10 in FIG. 16G. After separated, the second RDL 440 is exposed.

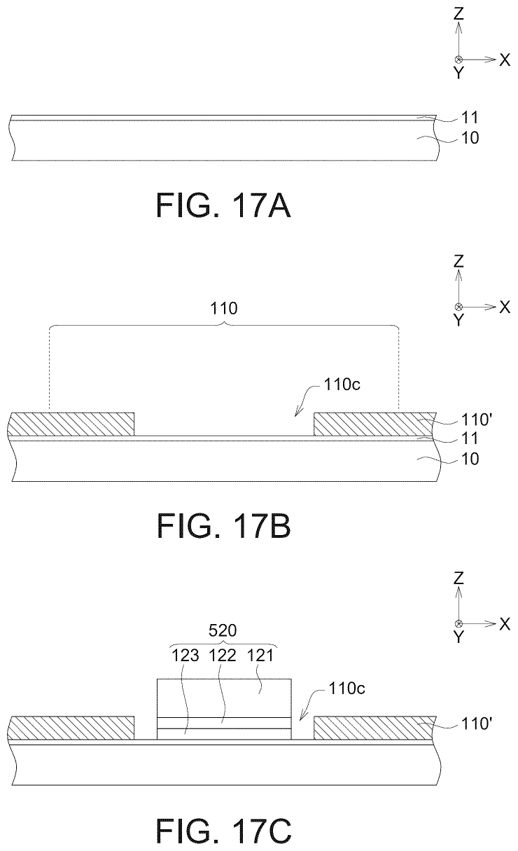

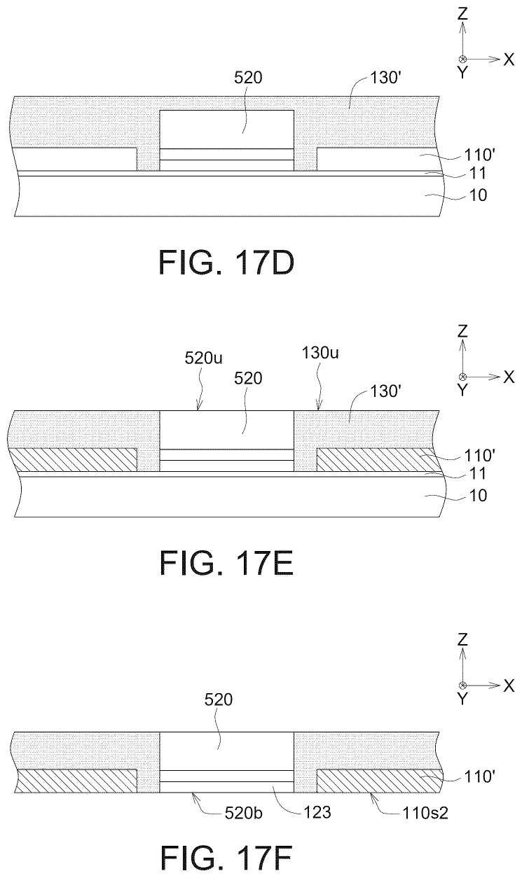

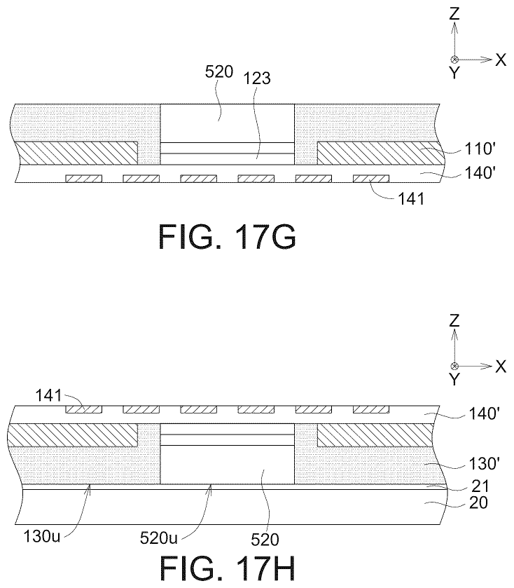

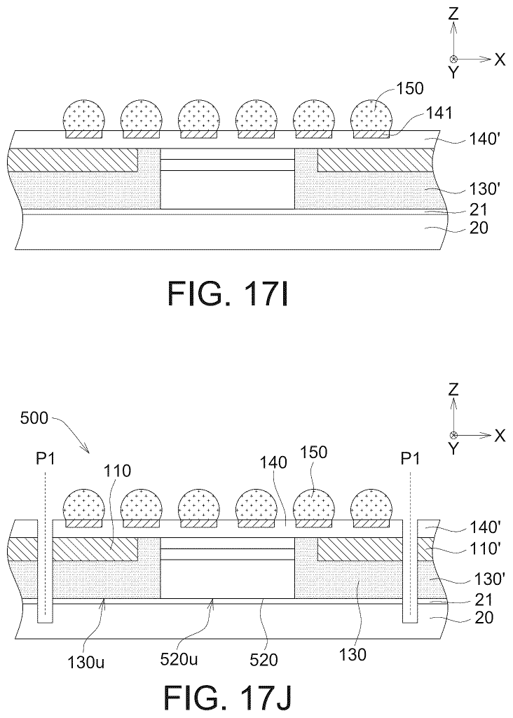

Referring to FIGS. 17A to 17J, FIGS. 17A to 17J illustrate schematic diagrams of manufacturing method of the semiconductor device 500 in FIG. 5 according to an embodiment.

As illustrated in FIG. 17A, the carrier 10 on which the release layer 11 is disposed is provided. In an embodiment, the release layer 11 is formed on the carrier 10 by using, for example, deposition.

As illustrated in FIG. 17B, the cage plate 110′ is disposed on the carrier 10 through the release layer 11. The cage plate 110′ includes at least one cage 110 each having the cavity 110c. When the cage plate 110′ includes a plurality of the cages 110, the cages 110 are connected with each other. The cage 110 may be divided by using, for example, singulation in subsequent process.

As illustrated in FIG. 17C, at least one semiconductor chip 520 disposed on the carrier 10 through the release layer 11. Each semiconductor chip 520 is disposed in the corresponding cavity 110c of the cage plate 410′. The semiconductor chip 520 includes the base 121, the FEOL structure 122 and the BEOL structure e 123. Compared to the semiconductor chip 120, the semiconductor chip 520 may omit the contact 124. The semiconductor chip 520 is disposed on the carrier 10 by the BEOL structure 123.

As illustrated in FIG. 17D, the package body material 130′ covering the semiconductor chip 520 and the cage plate 110′ is formed by using, for example, transfer molding, compression molding, etc. The package body material 130′ covers the lateral surfaces of the semiconductor chip 520 and fills up a portion of the cavity 110c.

As illustrated in FIG. 17E, a portion of the package body material 130′ may be removed to expose the chip surface 520u of the semiconductor chip 520 by using, for example, grinding, CMP, etc. After singulation, the package body material 130′ forms the package surface 130u, and the package surface 130u and the chip surface 520u are aligned with (for example, flushed with) each other.

As illustrated in FIG. 17F, the carrier 10 with the release layer 11 is removed from the carrier 10, wherein the chip surface 520b of the BEOL structure 123 of the semiconductor chip 520 and the second cage surface 110s2 of the cage plate 110′ are exposed.

As illustrated in FIG. 17G, the first RDL structure 140′ over the cage plate 110′ and the BEOL structure 123 of the semiconductor chip 520 is formed by using, for example, plating, lithography, deposition, etching, etc. The first RDL structure 140′ includes at least one conductive pad 141.

As illustrated in FIG. 17H, the structure in FIG. 17G is inverted to make the first RDL structure 140′ face up, and then is disposed on the carrier 20 through the release layer 21, wherein the package surface 130u and the chip surface 520u is disposed on the carrier 20, and the conductive pads 141 face up.

As illustrated in FIG. 17I, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 17J, at least one singulation passage P1 passing through the first RDL structure 140′, the cage plate 110′, the package body material 130′ and a portion of the carrier 20 is formed to form at least one semiconductor device 500 by using, for example, sawing (such as diamond blade sawing or laser sawing), etc. After singulation, the cage plate 110′ forms at least one cage 110, the first RDL structure 140′ forms at least one first RDL 140, the package body material 130′ forms at least one package body 130. After singulation, each semiconductor device 500 includes the cage 110, at least one semiconductor chip 520, the package body 130, the first RDL 140 and at least one contact 150.

Then, the semiconductor device 500 is separated from the release layer 21 and the carrier 20 in FIG. 17J. After separated, the chip surface 520u of the semiconductor chip 520 and the package surface 130u of the package body 130 are exposed.

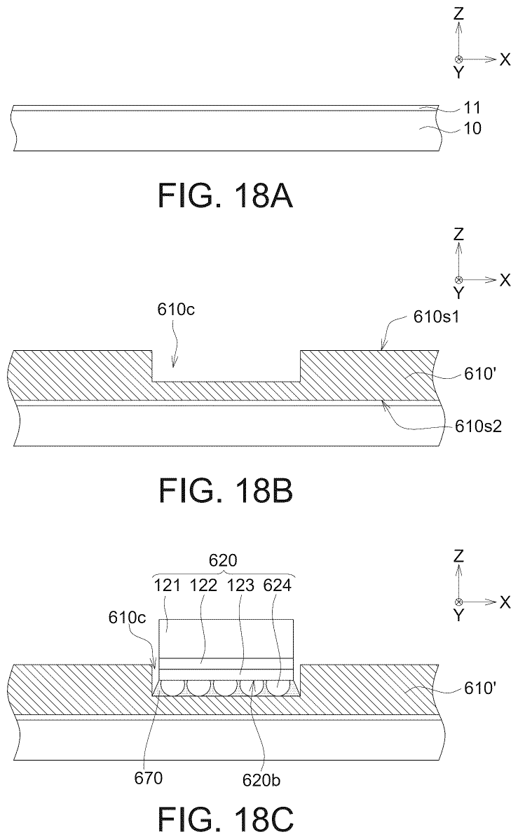

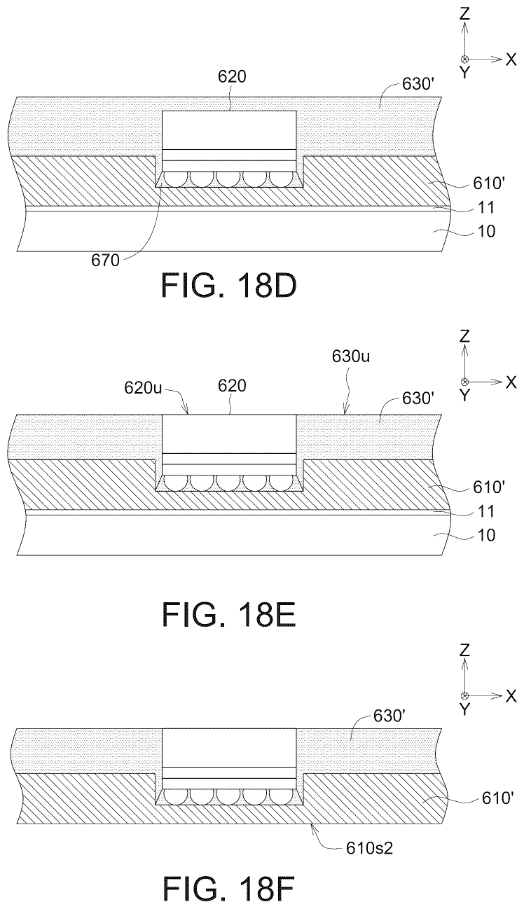

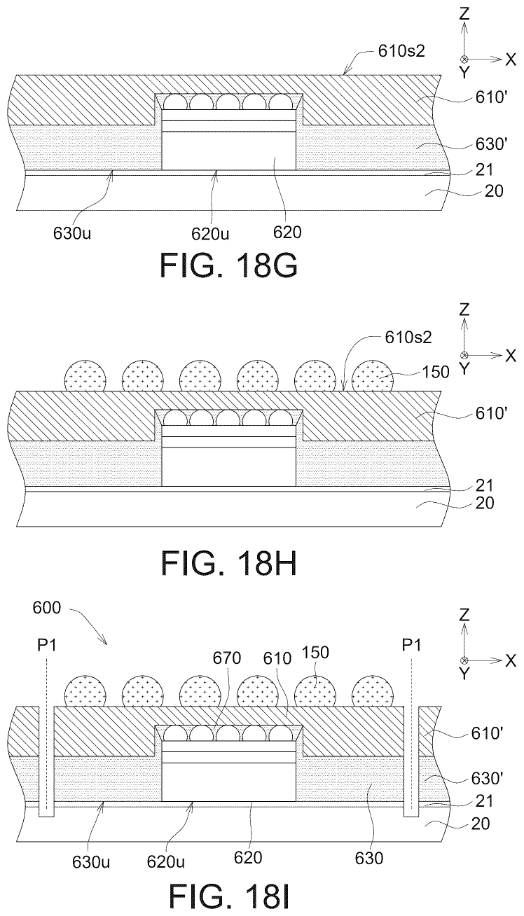

Referring to FIGS. 18A to 18I, FIGS. 18A to 18I illustrate schematic diagrams of manufacturing method of the semiconductor device 600 in FIG. 6 according to an embodiment.

As illustrated in FIG. 18A, the carrier 10 on which the release layer 11 is disposed is provided. In an embodiment, the release layer 11 is formed on the carrier 10 by using, for example, deposition.

As illustrated in FIG. 18B, a cage plate 610′ is disposed on the carrier 10 through the release layer 11. The cage plate 610′ has the first cage surface 610s1, the second cage surface 610s2 opposite to the first cage surface 610s1 and has at least one cavity 610c extending towards the second cage surface 610s2 from the first cage surface 610s1. In the present embodiment, the cavity 610c is, for example, a blind hole. In the present embodiment, the cage plate 610′ may include at least one circuit element. The cage plate 610′ can be a laminate substrate, a silicon substrate, a high-thermal-conductivity substrate, a metal substrate, a combination thereof or based on other types of material.

As illustrated in FIG. 18C, at least one semiconductor chip 620 is disposed on a bottom surface of the cavity 610c. The semiconductor chip 620 is a flip chip having the chip surface 620b (for example, the active surface). The semiconductor chip 620 includes the base 121, the FEOL structure 122, the BEOL structure 123 and at least one contact 624. The base 121 is, for example, a portion of a silicon wafer. The FEOL structure 122 is formed in and/or on the base 121, the BEOL structure 123 is formed in and/or on the FEOL structure 122 and electrically connected with the FEOL structure 122, and the contact 624 is formed on the BEOL structure 123 and electrically connected with the BEOL structure 123. The contact 624 is disposed on and electrically connected with the chip surface 620b, and the contact 624 is, for example, a solder ball, a micro bump, a micro pillar, etc. The semiconductor chip 620 is electrically connected with the cage 610 through the contacts 624.

As illustrated in FIG. 18C, the underfill 670 covering the contacts 624 of the semiconductor chip 620 is formed by using, for example, dispensing, etc.

As illustrated in FIG. 18D, the package body material 630′ covering the semiconductor chip 620, the cage plate 610′ and the underfill 670 is formed by using, transfer molding, compression molding, etc.

As illustrated in FIG. 18E, a portion of the package body material 630′ may be removed to expose the chip surface 620u of the semiconductor chip 620 by using, for example, grinding, CMP, etc. After singulation, the package body material 630′ forms the package surface 630u, wherein the package surface 630u and the chip surface 620u are aligned with (for example, flushed with) each other.

As illustrated in FIG. 18F, the carrier 10 with the release layer 11 is removed to expose the second cage surface 610s2 of the cage plate 610′.

As illustrated in FIG. 18G, the structure in FIG. 18F is inverted to make the second cage surface 610s2 of the cage plate 610′ face up, and then the structure is disposed on the carrier 20 through the release layer 21, wherein the package surface 630u and the chip surface 620u are disposed on the carrier 20.

As illustrated in FIG. 18H, at least one contact 150 is formed on the second cage surface 610s2 of the cage plate 610′. A plurality of the contacts 150 is arranged as a grid array. The contact 150 is, for example, a solder ball (or called a BGA ball), micro bump, etc.

As illustrated in FIG. 18I, at least one singulation passage P1 passing through the cage plate 610′, the package body material 630′ and a portion of the carrier 20 is formed to form at least one semiconductor device 600 by using, for example, sawing (such as diamond blade sawing or laser sawing), etc. After singulation, the cage plate 610′ forms at least one cage 610, and the package body material 630′ forms at least one package body 630. After singulation, each semiconductor device 600 includes the cage 610, at least one semiconductor chip 620, the package body 630 and the underfill 670.

Then, the semiconductor device 600 is separated from the release layer 21 and the carrier 20 in FIG. 18I. After separated, the chip surface 620u of the semiconductor chip 620 and the package surface 630u of the package body 630 are exposed.

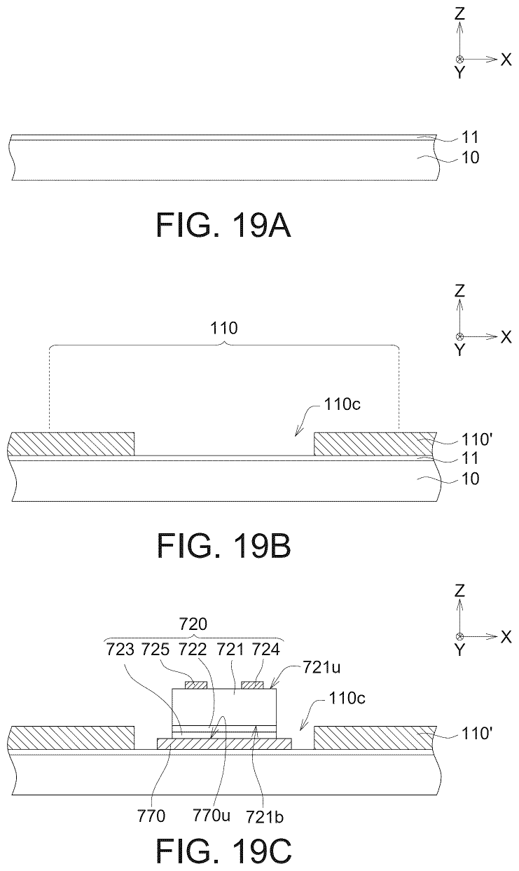

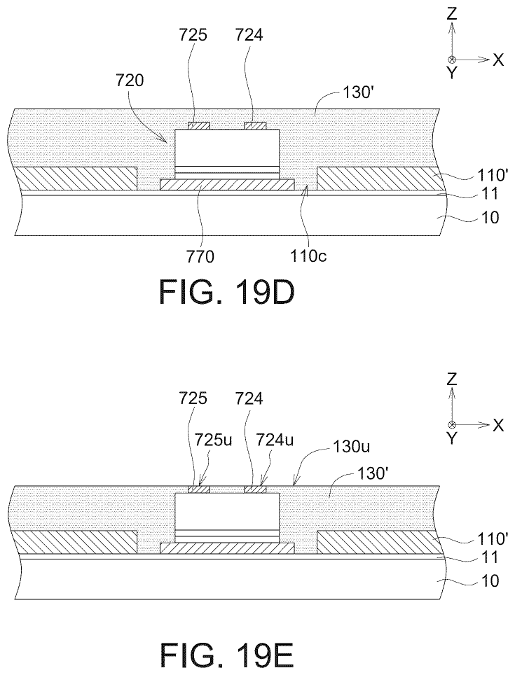

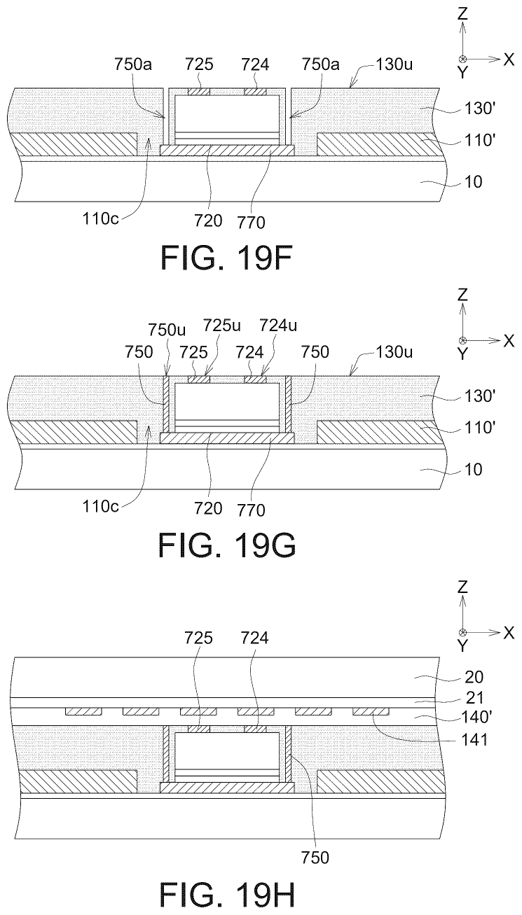

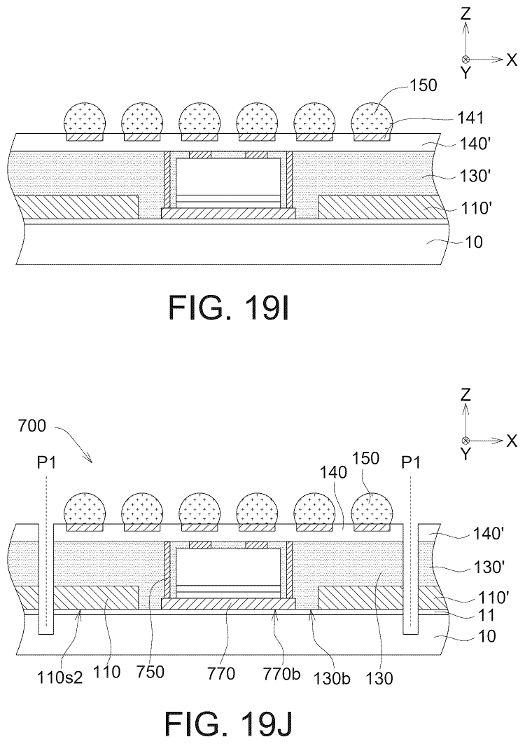

Referring to FIGS. 19A to 19J, FIGS. 19A to 19J illustrate schematic diagrams of manufacturing method of the semiconductor device 700 in FIG. 7 according to an embodiment.

As illustrated in FIG. 19A, the carrier 10 on which the release layer 11 is disposed is provided. In an embodiment, the release layer 11 is formed on the carrier 10 by using, for example, deposition.

As illustrated in FIG. 19B, the cage plate 110′ is disposed on the carrier 10 through the release layer 11. The cage plate 110′ includes at least one cage 110 each having the cavity 110c. When the cage plate 110′ includes a plurality of the cages 110, the cages 110 are connected with each other. The cage 110 may be formed by using, for example, singulation in subsequent process. The cage 110′ can be, for example, a thin, laminated photoresist.

As illustrated in FIG. 19C, at least one conductive layer 770 is disposed on the release layer 11 of the carrier 10 in the cavity 110c by using, for example, plating, deposition, etc. Then, at least one semiconductor chip 720 is disposed on the conductive layer 770. The semiconductor chip 720 includes the base 721, the electrode 722, the solder 723 and a plurality of the electrodes 724 and 725. The base 721 is, for example, a portion of a silicon wafer. Although not illustrated, the base 121 includes at least one transistor circuit. The electrode 722 is formed in and/or on the first surface 721b of the base 721, the solder 723 is formed in and/or on the electrode 722 and electrically connected with the electrode 722. The semiconductor chip 720 is disposed on the conductive layer 770 through the solder 723. The transistor circuit in the base 721 is electrically connected with the conductive layer 770 through the electrode 722 and the solder 723. The electrode 724 and the electrode 725 are formed on the second surface 721u of the base 721. The electrodes 724 and 725 are, for example, solder bump, solder balls, etc. The semiconductor chip 720 is disposed on a local portion of a surface 770u of the conductive layer 770, and another portion of the surface 770u of the conductive layer 770 is exposed (not covered by the semiconductor chip 720).

As illustrated in FIG. 19D, the package body material 130′ covering the semiconductor chip 720, the cage plate 110′ and the conductive layer 770 is formed by using, for example, transfer molding, compression molding, etc. The package body material 130′ covers the lateral surfaces of the semiconductor chip 720 and fills up a portion of the cavity 110c.

As illustrated in FIG. 19E, a portion of the package body material 130′ may be removed to expose the electrodes 724 and 725 of the semiconductor chip 720 by using, for example, grinding, CMP, etc. After, the electrode 724 forms an electrode surface 724u, the electrode 725 forms an electrode surface 725u, and the package body material 130′ forms the package surface 130u, wherein the electrode surface 724u, the electrode surface 725u and the package surface 130u are, for example, aligned with (for example, flushed with) each other.

As illustrated in FIG. 19F, at least one hole 750a extending to the conductive layer 770 from the package surface 130u of the package body 130 is formed by using, for example, laser drill, lithography, etching, etc.

As illustrated in FIG. 19G, at least one conductive portion 750 filling the corresponding hole 750a is formed by using, for example, plating, deposition, etc., wherein the conductive portion 750 is electrically connected with the conductive layer 770. In an embodiment, if necessary, a portion of the package body material 130′ and a portion of the conductive portion 750 may be removed to expose the electrodes 724 and 725 of the semiconductor chip 720 by using, for example, grinding, CMP, etc. In an embodiment, the electrode surface 724u, the electrode surface 725u, the package surface 130u and a conductive surface 750u of the conductive portion 750 are, for example, aligned with (for example, flushed with) each other.

As illustrated in FIG. 19H, the first RDL structure 140′ on the carrier 20 is transferred to the semiconductor chip 720, the conductive portions 750 and the package body material 130′ in FIG. 19G. Before transferring, the first RDL structure 140′ may be pre-formed on the carrier 20 by using, for example, at least one semiconductor process (for example, deposition, lithography, plating, etching etc.). In an embodiment, the first RDL structure 140′ may be formed on the release layer 21 which is disposed on the carrier 20. The first RDL structure 140′ is electrically connected with the electrodes 724 and 725 of the semiconductor chip 720 and the conductive portion 750.

As illustrated in FIG. 19I, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 19J, at least one singulation passage P1 passing through the first RDL structure 140′, the cage plate 110′, the package body material 130′ and a portion of the carrier 10 is formed to form at least one semiconductor device 700 by using, for example, sawing (such as diamond blade sawing or laser sawing), etc. After singulation, the cage plate 110′ forms at least one cage 110, the first RDL structure 140′ forms at least one first RDL 140, the package body material 130′ forms at least one package body 130. After singulation, each semiconductor device 700 includes the cage 110, at least one semiconductor chip 720, the package body 130, the first RDL 140, at least one contact 150, at least one conductive portion 750 and at least one conductive layer 770.

Then, the semiconductor device 700 is separated from the release layer 11 and the carrier 10 in FIG. 19J. After separated, the second cage surface 110s2 of the cage 110, a conductive surface 770b of the conductive layer 770 and the package surface 130b of the package body 130 are exposed.

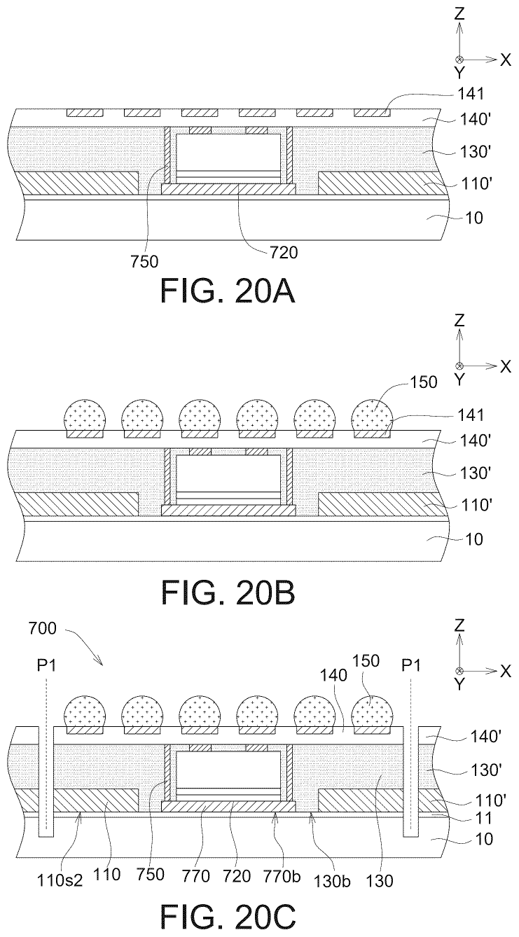

Referring to FIGS. 20A to 20C, FIGS. 20A to 20C illustrate schematic diagrams of manufacturing method of the semiconductor device 700 in FIG. 7 according to another embodiment.

As illustrated in FIG. 20A, after step in FIG. 19G, the first RDL structure 140′ is formed on the package body material 130′, the semiconductor chip 720 and the conductive portion 750 by using, for example, plating, lithography, deposition, etching, etc. The conductive pad 141 of the first RDL structure 140′ is exposed and faces up. The first RDL structure 140′ is electrically connected with the conductive portion 750 and the electrodes 724 and 725 of the semiconductor chip 720. In the present embodiment, the first RDL structure 140′ is formed by a process other than transferring. In other words, the first RDL structure 140′ is directly formed on the package body material 130′, the semiconductor chip 720 and the conductive portions 750 without the carrier 20.

As illustrated in FIG. 20B, at least one contact 150 is formed on the conductive pad 141 of the first RDL structure 140′. A plurality of the contacts 150 is arranged as a grid array. The contact 150 is, for example, a solder ball (or called a BGA ball), micro bump, etc.

As illustrated in FIG. 20C, at least one singulation passage P1 passing through the first RDL structure 140′, the cage plate 110′, the package body material 130′ and a portion of the carrier 10 is formed to form at least one semiconductor device 700 by using, for example, sawing (such as diamond blade sawing or laser sawing), etc. After singulation, the cage plate 110′ forms at least one cage 110, the first RDL structure 140′ forms at least one first RDL 140, the package body material 130′ forms at least one package body 130. After singulation, each semiconductor device 700 includes the cage 110, at least one semiconductor chip 720, the package body 130, the first RDL 140, at least one contact 150, at least one conductive portion 750 and at least one conductive layer 770.

Then, the semiconductor device 700 is separated from the release layer 11 and the carrier 10 in FIG. 20C. After separated, the second cage surface 110s2 of the cage 110, a conductive surface 770b of the conductive layer 770 and the package surface 130b of the package body 130 are exposed.

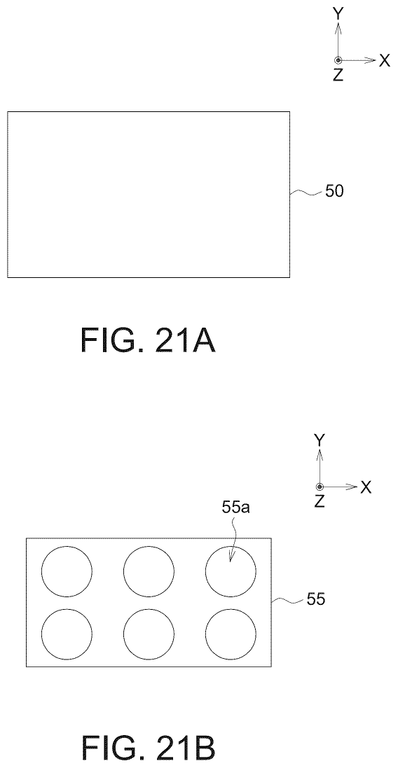

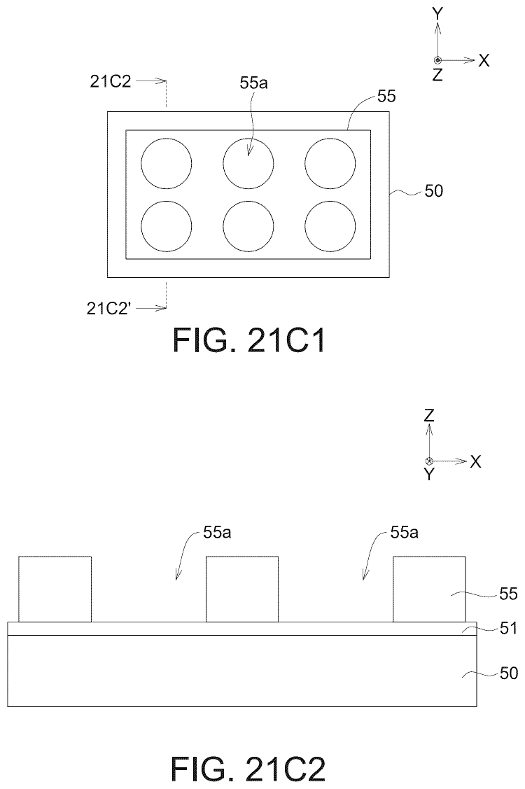

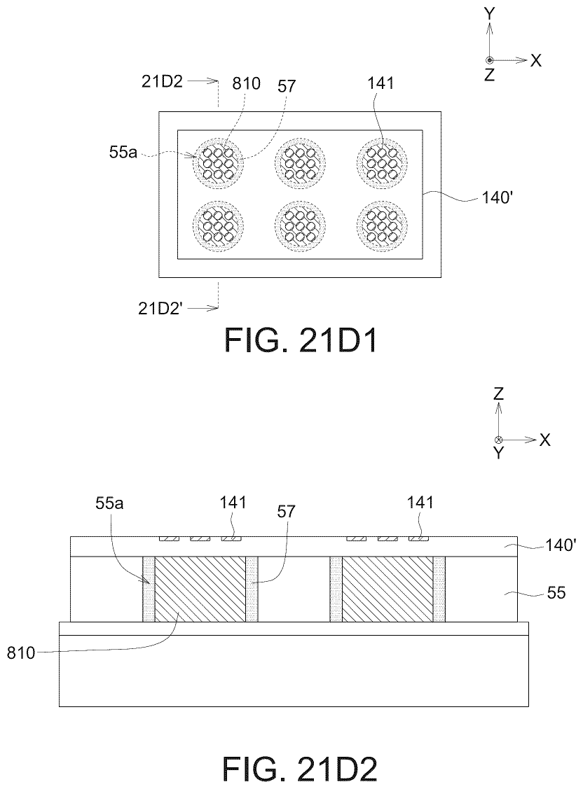

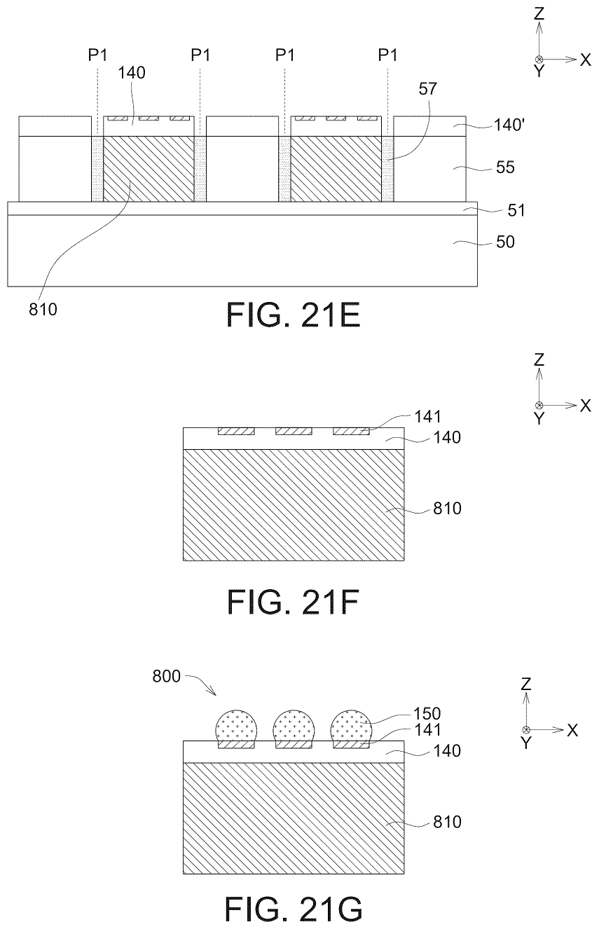

Referring to FIGS. 21A to 21G, FIGS. 21A to 21G illustrate schematic diagrams of manufacturing method of the semiconductor device 800 in FIG. 8 according to an embodiment.

As illustrated in FIG. 21A, a carrier 50 is provided. The carrier 50 is, for example, a glass.

As illustrated in FIG. 21B, a spacer 55 is provided, wherein the spacer 55 has at least one hole 55a. In the present embodiment, the hole 55a is, for example, a through hole. The spacer 55 may be formed of a material including polyimide, metallic, etc.

As illustrated in FIGS. 21C1 and 21C2, FIG. 21C2 illustrates a schematic diagram of a cross-sectional view of s structure of FIG. 21C1 along a direction 21C2-21C2′. The spacer 55 is disposed on the carrier 50 through a release layer 51, wherein the release layer 51 is formed on the carrier 50 by using, for example, deposition.

As illustrated in FIGS. 21D1 and 21D2, FIG. 21D2 illustrates a schematic diagram of a cross-sectional view of the structure in FIG. 21D1 along a direction 21D2-21D2′. At least one substrate 810 is disposed in the hole 55a, wherein each substrate 810 is disposed within the corresponding hole 55a. Then, a filler 57 filling up a space between the substrate 810 and a sidewall of the hole 55a is formed by using, for example, coating, dispensing, molding, etc. Then, the first RDL structure 140′ over the substrate 810 and the filler 57 is formed by using, for example, plating, lithography, deposition, etching, etc. The first RDL structure 140′ includes at least one conductive pad 141, and the conductive pad 141 are located above the substrate 810. In other words, the conductive pad 141 and the substrate 810 overlap in Z-axis. The filler 57 may fix a relative position between the spacer 55 and the substrate 810. The filler 57 here can be a polymeric encapsulant commonly found in IC packaging or in LCD driver IC packaging, an oxide, silicon-based material, etc. In an embodiment, the substrate 810 is, for example, a semiconductor wafer which has not been cut. The substrate 810 may include at least one integrated circuit (IC). In addition, the substrate 810 has a thickness (for example, in Z-axis) equal to that of the spacer 55.

As illustrated in FIG. 21E, at least one singulation passage P1 passing through the first RDL structure 140′ along an edge of the substrate 810 by using, for example, laser cut, etc. After singulation, the first RDL structure 140′ forms at least one first RDL 140.

Then, a photodissociation (for example, illuminating with UV (ultraviolet)) is performed on the filler 57 and the release layer 51 (in the case of an UV release-able layer is used) in FIG. 21E. Preferably, the spacer 55 may be reused.

As illustrated in FIG. 21F, the structure including the first RDL 140 and the substrate 810 is separated from the filler 57 and the release layer 51 after photodissociation.

As illustrated in FIG. 21G, at least one contact 150 is formed on the conductive pad 141 of the first RDL 140 to form the semiconductor device 800. A plurality of the contacts 150 is arranged as a grid array. The contact 150 is, for example, a solder bump, a solder ball (or called a BGA ball). Then, the semiconductor device 800 in FIG. 21G may be singulated, by using, for example, sawing (such as diamond blade sawing or laser sawing), to form a plurality of semiconductor dies.

In another embodiment, the structure in FIG. 21F may be singulated, by using, for example, sawing (such as diamond blade sawing or laser sawing), to form a plurality of semiconductor dies, and then at least one contact 150 is formed on the conductive pads 141 of the first RDL 140 of the semiconductor die, to form the semiconductor device 800 in FIG. 21G.

Referring to FIGS. 22A and 22B, FIG. 22A illustrates a schematic diagram of a panel-level packaging according to an embodiment, and FIG. 22B illustrates a schematic diagram of a cross-sectional view of the panel-level packaging in FIG. 22A along a direction 22B-22B′.

Fan-out panel-level packaging (FOPLP) promises to significantly lower assembly costs over FOWLP by as much as 30 to 40%, provided that the relevant processes for die placement, molding, and redistribution layers (RDL) formation can be scaled up with equivalent yields. Today, FOPLP has been adopted for low-end/mid-end, high-volume applications such as PMICs using relatively relaxed dimensions such as a line/space (L/S) of ≥10 μm/10 μm and looser RDL.

As illustrated in FIGS. 22A and 22B, in a panel-level packaging (for example, a fan-out panel-level packaging or a fan-in panel-level packaging), a plurality of the semiconductor devices 900 is disposed on the carrier 10 through the release layer 11. Each semiconductor device 900 is, for example, a semiconductor die, such as an active die or a passive device. In another embodiment, such semiconductor die may be pre-bumped prior to FOPLP with solder bumps, copper pillar micro-bumps, gold bumps or other suitable bumps for fine pitch taking advantage of the mature, high-yield, fine-L/S wafer-level processes (compared to the relatively new via opening/metal fill in large-panel fan-out panel-level processing). The package body material 130′ includes a plurality of package islands 130A, wherein there is a dicing street DS formed adjacent two of the package islands 130A. As a result, it can minimize the CTE (Coefficient of Thermal Expansion) mismatch, mold flow and other effects. A lower-CTE, lower-modulus molding compound or encapsulation material, and adaptive patterning can be used to minimize warpage effects.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a cage having a first cage surface, a second cage surface opposite to the first cage surface and a cavity extending towards the second cage surface from the first cage surface;
a semiconductor chip disposed in the cavity;
a package body covering the semiconductor chip; and
a first RDL (redistribution layer) over the package body and the semiconductor chip.

2. The semiconductor device according to claim 1, wherein the cavity extends to the first cage surface.

3. The semiconductor device according to claim 1, wherein the semiconductor chip has a chip back surface, and the chip back surface of the semiconductor chip and the second cage surface of the cage are flushed with each other.

4. The semiconductor device according to claim 1, wherein the semiconductor chip protrudes relative to the first cage surface of the cage.

5. The semiconductor device according to claim 1, wherein the package body has a package lateral surface, the cage has a cage lateral surface, and the package lateral surface and the cage lateral surface are flushed with each other.

6. The semiconductor device according to claim 1, wherein the cage has a cage lateral surface, and the package body covers the cage lateral surface and the first cage surface but exposes the second cage surface.

7. The semiconductor device according to claim 1, wherein the cavity is a blind hole in the cage which is a substrate, and the semiconductor chip is a flip chip having an active surface, and the flip chip is bonded to the substrate in the blind hole with the active surface facing the blind hole.

8. The semiconductor device according to claim 1, wherein the semiconductor chip is a flip chip having an active surface, the first RDL is disposed on the second cage surface and the active surface, and the package body covers the first cage surface of the cage.

9. The semiconductor device according to claim 1, further comprising:
a conductive layer within the cavity;
wherein the semiconductor chip is disposed on the conductive layer, the package body has a package surface and a through hole extending to the conductive layer from the package surface; and the semiconductor device further comprises a conductive portion within the through hole.

10. The semiconductor device according to claim 1, further comprising:
a conductive portion extending to the first cage surface from the second cage surface.

11. The semiconductor device according to claim 10, further comprising:
a second RDL disposed on the second cage surface; and
a third RDL disposed on the first cage surface, wherein the third RDL is disposed between the first RDL and the first cage surface;
wherein the conductive portion electrically connects the second RDL with the third RDL.

12. The semiconductor device according to claim 10, wherein the package body is disposed within the cavity and disposed between a lateral surface of the semiconductor chip and a lateral surface of the cavity.

13. A manufacturing method, further comprising:
disposing a cage on a carrier, wherein the cage has a first cage surface, a second cage surface opposite to the first cage surface and a cavity extending toward the second cage surface from the first cage surface;
disposing a semiconductor chip in the cavity;
disposing a package body to cover the semiconductor chip;
disposing a first RDL over the package body and the semiconductor chip; and
removing the carrier to expose the first RDL.

14. The manufacturing method according to claim 13, wherein step of disposing the first RDL over the package body and the semiconductor chip comprises:
disposing the first RDL on a carrier;
transfer the first RDL to the package body and the semiconductor chip through the carrier; and
removing the carrier.

15. The manufacturing method according to claim 13, further comprising:
removing the cage and a portion of the semiconductor chip.

16. The manufacturing method according to claim 13, wherein in step of disposing the package body to cover the semiconductor chip, the package body further covers a lateral surface of the cage.

17. The manufacturing method according to claim 13, wherein the cage containing the cavity in form of a blind hole is disposed on the carrier; and the semiconductor chip is a flip chip bonded in the blind hole with an active surface facing the blind hole.

18. The manufacturing method according to claim 13, further comprising:
disposing a conductive layer within the cavity;
disposing the semiconductor chip on the conductive layer in the cavity;
disposing the package body to cover the semiconductor chip;
forming a through hole which extends to the conductive layer from a package surface of the package body; and
forming a conductive portion within the through hole.

19. The manufacturing method according to claim 13, wherein step of disposing the cage on the carrier comprising:
forming a conductive portion, wherein the conductive portion extends to the first cage surface from the second cage surface.

20. The manufacturing method according to claim 19, wherein step of disposing the cage on the carrier comprising:
disposing a second RDL on the second cage surface; and
disposing a third RDL on the first cage surface, wherein the third RDL is disposed between the first RDL and the first cage surface, and the conductive portion electrically connecting the second RDL with the third RDL.
